(19) United States
(12) Patent Application Publication
(10) Pub. No.: US 2010/0085344 A1
(43) Pub. Date: Apr. 8, 2010

(54) OPERATIONAL AMPLIFIER CIRCUIT AND DISPLAY APPARATUS

(75) Inventors: Munehiko OGAWA, Kyoto (JP); Kazuyoshi NISHI, Kyoto (JP); Hiroshi KOJIMA, Shiga (JP); Tomokazu KOJIMA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/568,945

(22) Filed: Sep. 29, 2009

(30) Foreign Application Priority Data
Oct. 6, 2008 (JP) 2008-259249
Jun. 19, 2009 (JP) 2009-146836

(51) Int. Cl. G06F 3/038; H03F 3/45

(52) U.S. Cl. 345/211; 330/253; 345/82

(57) ABSTRACT

An operational amplifier circuit according to an aspect of the present invention includes a differential amplifier unit. The differential amplifier circuit includes a first differential transistor and a second differential transistor, which form a first differential pair, and a current source transistor which supplies a current to the first differential pair. The operational amplifier circuit further includes a first variable resistive element connected between (i) at least one of sources of the first and the second differential transistors and (ii) a drain of the current source transistor. The first variable resistive element includes: a first terminal and a second terminal; first resistive elements connected in series; and a first correction voltage selecting circuit which modifies a resistance value between the first and the second terminals by changing the number of stages of the first resistive elements connected in series between the first and the second terminals.

### BACKGROUND OF THE INVENTION

(1) Field of the Invention

The present invention relates to an operational amplifier circuit and a display apparatus, and particularly to an operational amplifier circuit including a differential amplifier unit.

(2) Description of the Related Art

In recent years, liquid crystal panels and organic electroluminescent panels have been used for portable devices, compact mobile devices, and large panel devices. The liquid crystal panels and the organic electroluminescent panels are also used for display apparatuses in video systems such as television sets, of which market is increasingly expanding. Such display apparatuses are under development for a larger number of gradation levels (from 8 bits to 10 bits and then to 12 bits) and higher definition in display panels to improve image fidelity. In addition, display driver LSI in the display apparatuses is required to reduce output voltage variation among their output terminals.

For example, Patent Reference 1: Japanese Unexamined Patent Application Publication No. 2007-116493 and Patent Reference 2: Japanese Unexamined Patent Application Publication No. 6-35414 have disclosed related arts for reducing such output voltage variation.

An output circuit 300 described in Patent Reference 1 will be explained below.

FIG. 18 is a diagram showing a configuration of the output circuit 300 in Patent Reference 1.

In the output circuit 300 shown in FIG. 18, multiple sets of resistors and switches are connected in parallel to sources of differential transistors in a differential stage and a drain of a current source transistor in the differential stage.

The output circuit 300 shown in FIG. 18 includes an op amp having differential transistors 302, 304 and is provided with a resistor RA1 connected between the one differential transistor 302 and a node 306 and with a resistor RB1 connected between the other differential transistor 304 and the node 306.

Furthermore, multiple sets of resistors RA2, RA3, RA4, . . . , and switches 310 are all connected between the differential transistor 302 and the node 306, and likewise, multiple sets of resistors RB2, RB3, RB4, . . . , and switches 310 are all connected between the differential transistor 304 and the node 306.

The following will describe operations of the output circuit 300 configured as above.

Firstly, all the switches 310 connected to the resistors RA2, RA3, RA4, . . . , are turned on while all the switches 310 connected to the resistors RB2, RB3, RB4, . . . , are turned off. In this state, the output circuit 300 produces output. Because the resistors RA2, RA3, RA4, . . . , are connected in parallel, the voltage between the source of the differential transistor 304 and the node 306 becomes higher than the voltage between the source of the differential transistor 302 and the node 306 when the same amount of current flows through the differential transistors 302, 304. Accordingly, suppose that gate voltages of the differential transistors 302, 304 are equal to each other, indicating that there is no offset, then the output voltage of the output circuit 300 is stabilized at a value higher than an input voltage to an input 320.

As explained above, all the switches 310 connected to the resistors RA2, RA3, RA4, . . . , connected in parallel are controlled in the output circuit 300. This means that a change in the number of resistors connected in parallel leads to a change in the total resistance. The output voltage of the output circuit 300 is thus changed.

### SUMMARY OF THE INVENTION

Conventional display driving apparatuses having operational amplifier circuits (including the output circuit 300) which have output voltage variation even in the range of several tens of millivolts did not heavily affect displayed image quality thanks to its small number of gradation levels.

However, such output voltage variation in the range of several tens of millivolts can now cause deterioration in display image quality because of recent improvement in the panel development technologies and increase in the number of gradation levels. Operational amplifier circuits for liquid crystal panels and organic light emitting panels are therefore required to reduce their output voltage variation.

Here, the output voltage variation represents variation which arises at random due to the manufacturing process. Improving the manufacturing process to reduce the output voltage variation to around several millivolts is difficult to achieve as it is very time-consuming and costly.

Meanwhile, the output voltage variation may be reduced by addition of circuitry as described in Patent Reference 1. This however causes an increase in area of the circuit in the display driving apparatus. It is to be noted that display driving apparatuses especially for liquid crystal panels and organic electroluminescent panels are required to be smaller. This means that such an increase in area of the circuit should preferably be avoided as much as possible.

Thus, an object of the present invention is to provide an operational amplifier circuit capable of reducing the output voltage variation with less increase in circuit area and to provide a display apparatus having the operational amplifier circuit.

To achieve the abovementioned object, the operational amplifier circuit according to an aspect of the present invention is an operational amplifier circuit including:

a differential amplifier unit including a first differential transistor and a second differential transistor, which form a first differential pair, and a current source transistor which supplies a current to the first differential pair; and

a first variable resistive element connected between (i) at least one of a source of the first differential transistor and a source of the second differential transistor and (ii) a drain of the current source transistor,

wherein the first variable resistive element includes:

a first terminal and a second terminal;

first resistive elements connected in series; and

a first correction voltage selecting circuit which modifies a resistance value between the first terminal and the second terminal by changing the number of stages of the first resistive elements connected in series between the first terminal and the second terminal.

With this configuration, the operational amplifier circuit according to the aspect of the present invention can reduce the output voltage variation by setting the resistance of the first variable resistive element at a value such that the output voltage variation is smaller.

Further, the operational amplifier circuit according to the aspect of the present invention has the first variable resistive element which includes the multiple first resistive elements connected in series. This allows the operational amplifier circuit according to the aspect of the present invention to have a smaller area than an operational amplifier circuit having a variable resistive element which includes multiple resistive elements connected in parallel. Furthermore, the operational amplifier circuit according to an aspect of the present invention is capable of setting adjustment intervals for the output voltage variation to equal intervals with ease.

The operational amplifier circuit according to the aspect of the present invention is thus capable of reducing the output voltage variation with less increase in circuit area.

In addition, the operational amplifier circuit may further include

a second variable resistive element,

wherein the first variable resistive element is connected between the source of the first differential transistor and the drain of the current source transistor, and

the second variable resistive element is connected between the source of the second differential transistor and the drain of the current source transistor, and includes:

a third terminal and a fourth terminal;

second resistive elements connected in series; and

a second correction voltage selecting circuit which modifies a resistance value between the third terminal and the fourth terminal by changing the number of stages of the second resistive elements connected in series between the third terminal and the fourth terminal.

With this configuration, the operational amplifier circuit according to the aspect of the present invention is capable of reducing positive and negative output voltage variation.

In addition, the operational amplifier circuit may further include a correction polarity switching circuit which switches between a first mode and a second mode,

wherein the first mode indicates that the first variable resistive element is not connected between the source of the second differential transistor and the drain of the current source transistor, but connected between the source of the first differential transistor and the drain of the current source transistor, and

the second mode indicates that the first variable resistive element is not connected between the source of the first differential transistor and the drain of the current source transistor, but connected between the source of the second differential transistor and the drain of the current source transistor.

With this configuration, the operational amplifier circuit according to the aspect of the present invention is capable of reducing positive and negative output voltage variation. Moreover, the operational amplifier circuit according to the aspect of the present invention can be smaller in circuit area than an operational amplifier circuit having two variable resistive elements.

In addition, the operational amplifier circuit may further include a variable current source which selectively supplies a current having one of current values to the at least one of the source of the first differential transistor and the source of the second differential transistor.

With this configuration, the operational amplifier circuit according to the aspect of the present invention is capable of expanding an adjustment range of the output voltage variation and also setting shorter adjustment intervals for the output voltage variation.

In addition, the operational amplifier circuit may further include a variable voltage circuit which selectively outputs a voltage having one of voltage values to a gate of the current source transistor.

With this configuration, the operational amplifier circuit according to the aspect of the present invention is capable of expanding an adjustment range of the output voltage variation and also setting shorter adjustment intervals for the output voltage variation.

In addition, the first correction voltage selecting circuit may include first switches, each of which is provided for a corresponding one of the first resistive elements and which creates electrical conduction and an electrical disconnect between both terminals of the corresponding one of the first resistive elements.

With this configuration, the invention allows for the operational amplifier circuit having a small area, in which adjustment intervals of output voltage variation are equal.

In addition, the first resistive elements may have different resistance values from one another.

In addition, the first correction voltage selecting circuit may include first switches, each of which has a terminal connected to one of both ends and a connection node of a series connection of the first resistive elements and the other terminal connected to either the first terminal or the second terminal.

In addition, each of the first resistive elements may have a temperature dependent resistance value of which dependence is opposite to dependence of temperature dependent resistance values of the first switches.

With this configuration, the operational amplifier circuit according to the aspect of the present invention can be provided along with less temperature-dependent output voltage variation.

In addition, the first differential transistor and the second differential transistor may be n-channel MOS transistors.

In addition, the first differential transistor and the second differential transistor may be p-channel MOS transistors.

In addition, the first differential transistor and the second differential transistor may be n-channel MOS transistors, and the differential amplifier unit may further include a third differential transistor and a fourth differential transistor, which may be p-channel MOS transistors and form a second differential pair.

In addition, the operational amplifier circuit according to an aspect of the present invention includes:

a differential amplifier unit including a first differential transistor and a second differential transistor, which form a first differential pair, and a current source transistor which supplies a current to the first differential pair; and

a first variable resistive element connected between (i) at least one of a source of the first differential transistor and a source of the second differential transistor and (ii) a drain of the current source transistor,

wherein the first variable resistive element includes:

a first terminal and a second terminal;

a transistor having one of a source terminal and a drain terminal connected to the first terminal and the other one of the source terminal and the drain terminal connected to the second terminal; and

a variable voltage circuit which modifies on-resistance of the transistor by supplying a voltage having one of voltage values to the transistor.

With this configuration, the operational amplifier circuit according to the aspect of the present invention can reduce the output voltage variation by setting the resistance of the first variable resistive element at a value such that the output voltage variation is smaller.

Moreover, with the first variable resistive element including the transistor, the operational amplifier circuit according to the aspect of the present invention can be smaller in area.

The operational amplifier circuit according to the aspect of the present invention is thus capable of reducing the output voltage variation with less increase in circuit area.

In addition, a constant voltage may be applied to a gate terminal of the transistor, and

the variable voltage circuit may modify the on-resistance of the transistor by changing a substrate voltage of the transistor.

With this configuration, the operational amplifier circuit according to the aspect of the present invention is capable of modifying the resistance value of the first variable resistive element by changing a gate voltage of the transistor.

In addition, a constant substrate voltage may be applied to the transistor, and

the variable voltage circuit may modify the on-resistance of the transistor by changing a gate voltage of the transistor.

With this configuration, the operational amplifier circuit according to the aspect of the present invention is capable of modifying the resistance value of the first variable resistive element by changing the substrate voltage of the transistor.

In addition, a display apparatus according to an aspect of the present invention is a display apparatus for displaying an image according to image data, including:

a display panel which displays the image; and

a display driving apparatus which drives the display panel,

wherein the display panel includes:

light emitting pixels arranged in rows and columns; and

source lines each being provided for a corresponding one of the rows or the columns, and

the display driving apparatus includes the operational amplifier circuits, each of which is provided for a corresponding one of the source lines and outputs a signal voltage according to the image data to the corresponding one of the source lines.

With this configuration, the display apparatus according to the aspect of the present invention is capable of reducing unevenness in image appearing on the display panel, thereby allowing improvement in display image quality.

In addition, the display panel may be an organic electroluminescent panel.

With this configuration, the output voltage variation of the operational amplifier circuit can be reduced in the display apparatus having the organic electroluminescent panel, which requires further reduction in output voltage variation than liquid crystal panels.

It is to be noted that the present invention can be implemented not only as the above operational amplifier circuit but also as, for example, an operational amplifier circuit adjusting method for reducing the output voltage variation of the above operational amplifier circuit, and as a program causing a computer to execute the adjusting method for the above operational amplifier circuit. In addition, it goes without saying that such program may be distributed via a recording medium such as a Compact Disc-Read Only Memory (CD-ROM) and a communication network such as the Internet.

Furthermore, the invention may also be implemented as a semiconductor integrated circuit (LSI) which provides part or all of the functionality of the above operational amplifier circuit and as a display driving apparatus or a display apparatus which has the above operational amplifier circuit.

According to the above, the present invention can provide the operational amplifier circuit capable of reducing the output voltage variation with less increase in circuit area, and provide the display apparatus having the operational amplifier circuit.

### FURTHER INFORMATION ABOUT TECHNICAL BACKGROUND TO THIS APPLICATION

The disclosure of Japanese Patent Applications No 2008-259249 filed on Oct. 6, 2008 and No. 2009-146836 filed on Jun. 19, 2009 each including specification, drawings and claims are incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a diagram showing a configuration of a display apparatus according to an embodiment of the present invention;

FIG. 2 is a diagram showing a configuration of a driving unit according to an embodiment of the present invention;

FIG. 3 is a timing chart showing operation of a display apparatus according to an embodiment of the present invention;

FIG. 4 is a circuit diagram showing a comparative example of an operational amplifier circuit according to the first embodiment of the present invention;

FIG. 5 is a circuit diagram showing the operational amplifier circuit according to the first embodiment of the present invention;

FIG. 6 is a table showing one example of a resistance value of a variable resistive element according to the first embodiment of the present invention;

FIG. 7 is a flowchart showing an operational amplifier circuit adjusting method according to the first embodiment of the present invention;

FIG. 8 is a timing chart of an operational amplifier circuit adjusting method according to the first embodiment of the present invention;

FIG. 9 is a circuit diagram showing an operational amplifier circuit according to the second embodiment of the present invention;

FIG. 10 is a timing chart of an operational amplifier circuit adjusting method according to the second embodiment of the present invention, where positive output voltage variation is to be adjusted;

FIG. 11 is a timing chart of an operational amplifier circuit adjusting method according to the second embodiment of the present invention, where negative output voltage variation is to be adjusted;

FIG. 12 is a circuit diagram showing an operational amplifier circuit according to the third embodiment of the present invention;

FIG. 13 is a circuit diagram showing an operational amplifier circuit according to the fourth embodiment of the present invention;

FIG. 14 is a diagram showing a configuration of Variation of a variable resistive element according to an embodiment of the present invention;

FIG. 15 is a table showing one example of a resistance value of Variation of a variable resistive element according to an embodiment of the present invention;

FIG. 16 is a circuit diagram showing Variation of an operational amplifier circuit according to an embodiment of the present invention;

FIG. 17 is a circuit diagram showing Variation of an operational amplifier circuit according to an embodiment of the present invention; and

FIG. 18 is a circuit diagram showing a conventional output circuit.

### DESCRIPTION OF THE PREFERRED EMBODIMENT(S)

Hereinafter, embodiments of the present invention shall be described with reference to the drawings.

As the embodiments of the present invention, multiple embodiments will be explained below, which starts out with explanation of matters common to the multiple embodiments.

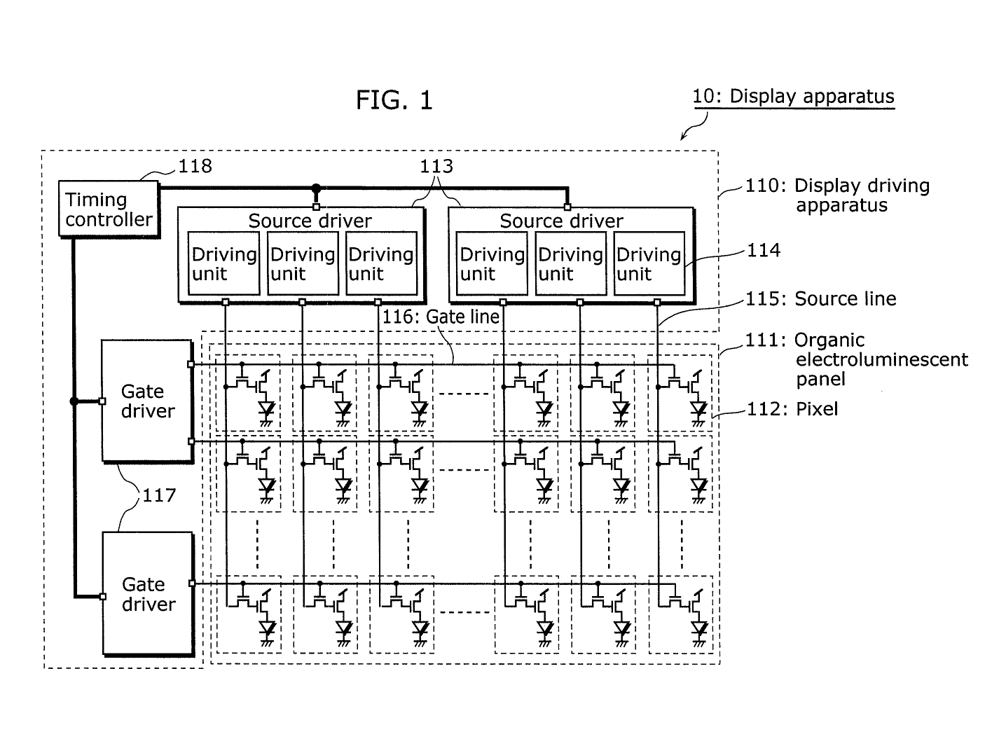

FIG. 1 is a block diagram showing a configuration of a display apparatus 10 according to an embodiment of the present invention.

A display apparatus 10 shown in FIG. 1 displays images according to image data inputted thereto. This display apparatus 10 includes an organic electroluminescent panel 111 and a display driving apparatus 110.

The organic electroluminescent panel 111 is a display panel which displays images according to image data. This organic electroluminescent panel 111 includes: multiple pixels 112 arranged in rows and columns; multiple source lines 115, each of which is provided for each of the columns; and multiple gate lines 116, each of which is provided for each of the rows.

Each of the pixels 112 includes an organic electroluminescent device. When a corresponding gate line 116 is selected, the organic electroluminescent device emits light in accordance with a voltage level of corresponding source line 115

The display driving apparatus 110 drives the organic electroluminescent panel 111. This display driving apparatus 110 includes multiple source drivers 113, multiple gate drivers 117, and a timing controller 118.

The source drivers 113 drive the multiple source lines 115. The multiple gate drivers 117 drive the multiple gate lines 116.

The timing controller 118 provides timing control for the source drivers 113 to drive the multiple source lines 115 and for the gate drivers 117 to drive the multiple gate lines 116.

The multiple source drivers 113 each include driving units 114, each of which is provided for each of the columns.

Although the display apparatus 10 shown in FIG. 1 has the multiple source drivers 113 and the multiple gate drivers 117, the display apparatus 10 having one source driver 113 and one gate driver 117 may also be possible.

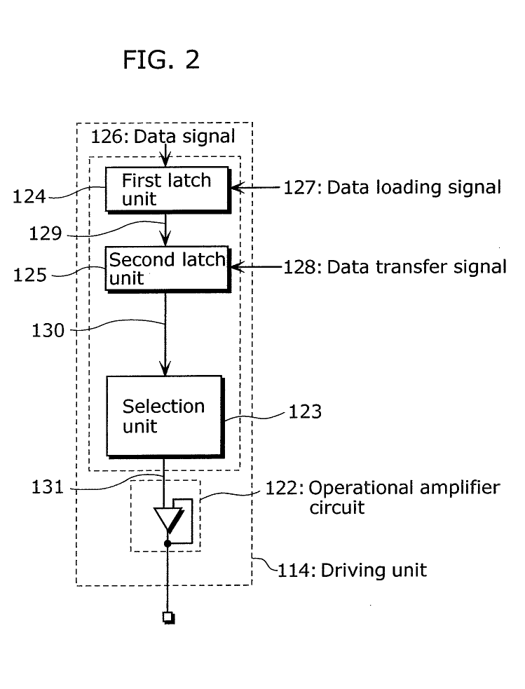

FIG. 2 is a diagram showing a configuration of the driving unit 114.

As shown in FIG. 2, the driving unit 114 includes an operational amplifier circuit 122, a selection unit 123, a first latch unit 124, and a second latch unit 125. To the driving unit 114, a data signal 126, a data loading signal 127, and a data transfer signal 128, which are outputted by the timing controller 118, are inputted. The data signal 126 corresponds to pixel data represented by the pixels. The data loading signal 127 inputted to one of the driving units 114 differ from the data loading signal 127 inputted to another of the driving units 114. In contrast, the data transfer signal 128 inputted to one of the driving units 114 is the same as the data transfer signal 128 inputted to another of the driving units 114.

The first latch unit 124 loads the data signal 126 upon changing of the data loading signal 127. The first latch unit 124 outputs the loaded data signal 126 as a first latch data 129.

The second latch unit 125 loads the first latch data 129 upon changing of the data transfer signal 128. The second latch unit 125 outputs the loaded first latch data 129 as a second latch data 130.

The selection unit 123 converts the second latch data 130, which is in digital form, into an analog signal 131 of analog voltage. To be specific, the selection unit 123 selects an analog voltage corresponding to the digital value of the second latch data 130 and outputs, as the analog signal 131, the selected analog voltage to the operational amplifier circuit 122.

The operational amplifier circuit 122 outputs to the source line 115 an analog voltage corresponding to the analog signal 131. That is, a signal voltage corresponding to image data is outputted to the source line 115 by the operational amplifier circuit 122.

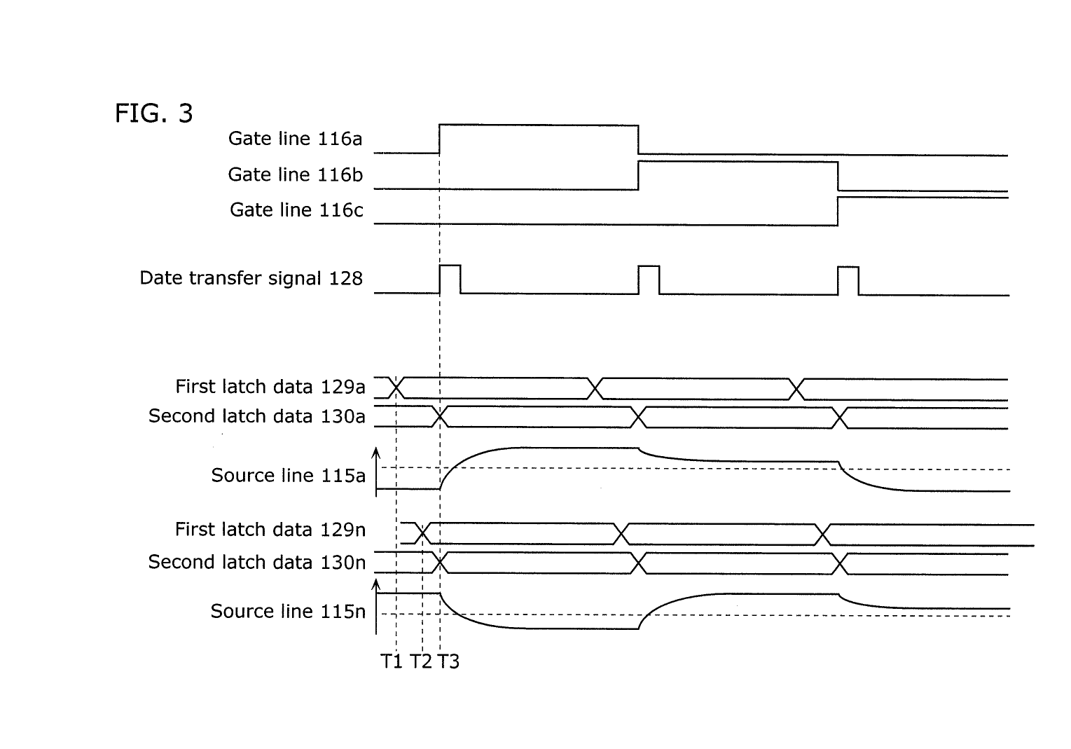

Next, operation of the display apparatus 10 configured as above shall be described. FIG. 3 is a timing chart showing operation of the display apparatus 10.

It is to be noted that the gate line 116a, gate line 116b, and gate line 116c, which are presented in FIG. 3, indicate signals passing through some of the multiple gate lines 116. For example, the gate lines 116a, 116b, 116c represent the first to third gate lines 116 from above, respectively.

First latch data 129a, second latch data 130a, and source line 115a correspond to a driving unit 114a, which means that first latch data 129n, second latch data 130n, and source line 115n correspond to a driving unit 114n. The driving unit 114a and the driving unit 114n are, for example, the driving units 114 which are located at both ends of array of the driving units 114.

At a time point T1 shown in FIG. 3, in accordance with the data loading signal 127, the first latch unit 124 loads the data signal 126 transmitted from the timing controller 118. This operation is performed sequentially for every driving unit 114 in the display apparatus 10.

At a time point T2, each and every one of the first latch units 124 has loaded the data signal 126.

Next, at a time point T3, the gate driver 117 outputs “HIGH” to only the gate line 116a according to a command from the timing controller 118. This HIGH state herein indicates a displayed state while a LOW state indicates a non-displayed state.

At a time point T3, the data transfer signal 128 rises. This causes each of the multiple second latch units 125 to load the first latch data 129 and transfer the second latch data 130 to the corresponding selection unit 123.

The selection unit 123 selects a desired analog voltage in accordance with the second latch data 130 transferred from the corresponding one of the second latch units 125, and outputs, as the analog signal 131, the selected analog voltage to the operational amplifier circuit 122.

The operational amplifier circuit 122 outputs to the source line 115 the analog voltage which corresponds to the analog signal 131 outputted from the selection unit 123.

Thus, the voltage corresponding to the image data is applied to the pixels 112 which are connected to the gate lines 116 in HIGH state. This indicates that repeatedly performing this operation for each row results in voltage application to all the pixels 112 in every single row. By doing so, the full-screen display, i.e., the display in one frame is achieved.

Hereinbelow, specific examples of the operational amplifier circuit 122 shall be described in the first to fourth embodiments.

### First Embodiment

In the first embodiment of the present invention, an operational amplifier circuit 122A, which is one example of the operational amplifier circuit 122 shown in FIG. 2, will be explained.

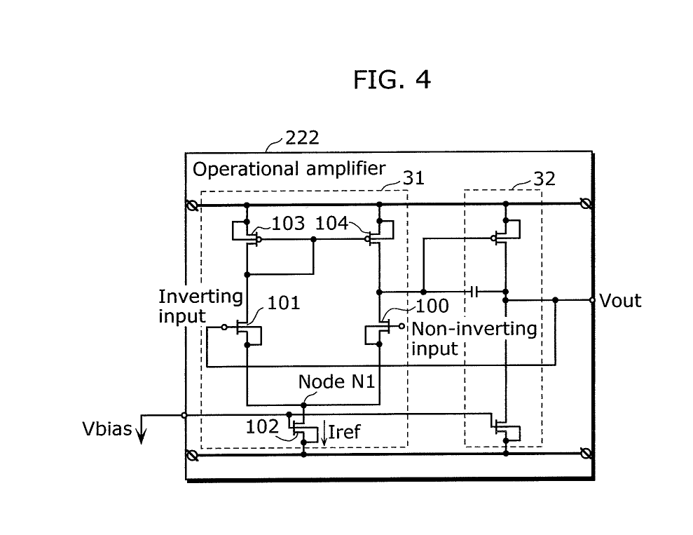

FIG. 4 is a view for comparison purposes, showing a circuit diagram of a commonly-used operational amplifier circuit 222.

The operational amplifier circuit 222 shown in FIG. 4 is an op amp which includes an inverting input terminal, a non-inverting input terminal, and an output terminal Vout.

The inverting input terminal is connected to the output terminal Vout. Through this connection, the operational amplifier circuit 222 outputs to the output terminal Vout a voltage which is equal in value to the voltage applied to the non-inverting input terminal.

This operational amplifier circuit 222 includes a differential amplifier unit 31 (differential stage) and an output unit 32 (output stage).

The differential amplifier unit 31 amplifies the difference in voltage between the inverting input terminal and the non-inverting input terminal, and outputs a voltage that indicates the amplified voltage difference. The output unit 32 outputs to the output terminal Vout the voltage outputted from the differential amplifier unit 31.

The differential amplifier unit 31 includes differential transistors 100, 101, which form a differential pair, a current source transistor 102 for supplying current to this differential pair, and load transistors 103, 104.

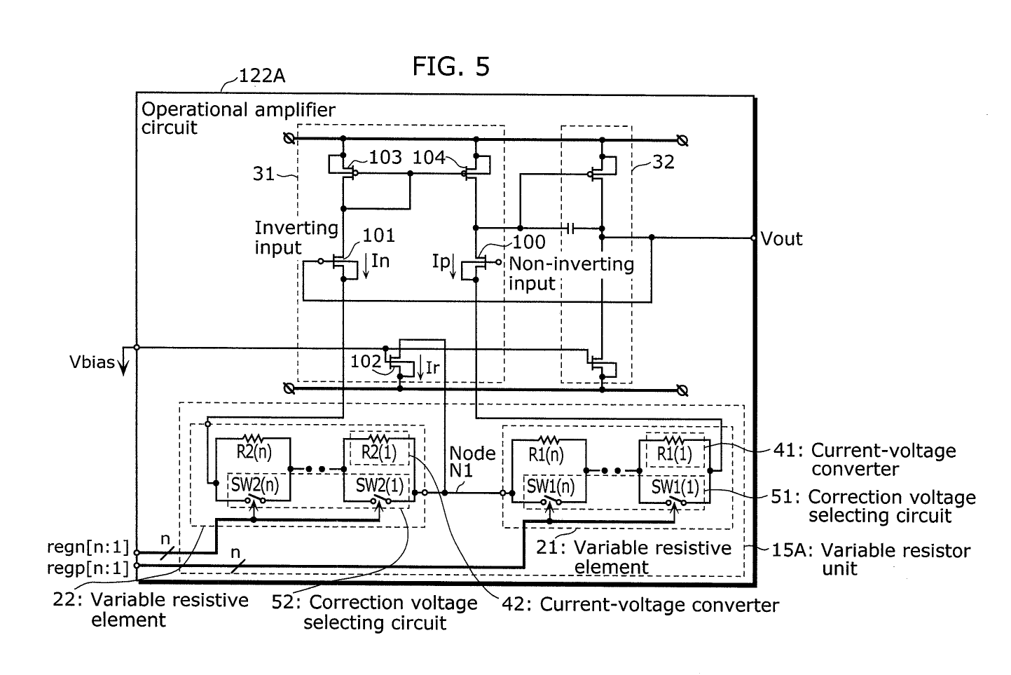

FIG. 5 is a circuit diagram showing the operational amplifier circuit 122A according to the first embodiment of the present invention. It is to be noted that the same numerals are used in FIG. 5 and the description to refer to the same or like elements as those shown in FIG. 4.

The operational amplifier circuit 122A shown in FIG. 5 includes a variable resistor unit 15A in addition to the configuration of the operational amplifier circuit 222 shown in FIG. 4. The variable resistor unit 15A is connected to a node N1 (a drain of the current source transistor 102), a source of the differential transistor 100 on a non-inverting input, and a source of the differential transistor 101 on an inverting input. A resistance value between the node N1 and the source of the differential transistor 100 is modified according to a control signal regp [n:1]. A resistance value between the node N1 and the source of the differential transistor 101 is modified according to a control signal regn [n:1]. This variable resistor unit 15A includes variable resistive elements 21, 22.

The variable resistive element 21 is connected between the source of the differential transistor 100 on the non-inverting input and the drain of the current source transistor 102. To be specific, the variable resistive element 21 has its first terminal connected to the source of the differential transistor 100 on the non-inverting input and its second terminal connected to the node N1. The variable resistive element 22 is connected between the source of the differential transistor 101 on the inverting input and the drain of the current source transistor 102. To be specific, the variable resistive element 22 has its third terminal connected to the source of the differential transistor 101 on the inverting input and its fourth terminal connected to the node N1.

The variable resistive element 21 includes n number (where n is an integer equal to or greater than 1) of current-voltage converters 41 connected in series, and a correction voltage selecting circuit 51.

The current-voltage converter 41 is a resistive element by which a current is converted into a voltage. The resistance values of n number of current-voltage converters 41 are different from one another.

The correction voltage selecting circuit 51 modifies the resistance value between the first terminal and the second terminal by changing the number of series-connected stages of the current-voltage converters 41 between the first terminal and the second terminal. The correction voltage selecting circuit 51 includes n number of switches SW1 (1) to SW1 (n). The n number of switches SW1 (1) to SW1 (n) are collectively denoted by a switch SW1 when not particularly distinguished from one another.

The n number of switches SW1 (1) to SW1 (n) are provided for the n number of current-voltage converters 41, respectively, and each of these switches is used to short or open both terminals of corresponding one of the current-voltage converters 41.

In other words, one current-voltage converter 41 and one switch SW1 are connected in parallel, which form one set, and the n number of the sets each having one current-voltage converter 41 and one switch SW1 are connected in series.

Opening and closing of the n number of switches SW1 (1) to SW1 (n) are controlled by n-bit variable resistive element control signals regp [n:1].

The variable resistive element 22, which has a similar configuration to the variable resistive element 21, includes n number of current-voltage converters 42 connected in series, and a correction voltage selecting circuit 52.

The current-voltage converters 42 are each a resistive element by which a current is converted into a voltage. The resistance values of n number of current-voltage converters 42 are different from one another.

The correction voltage selecting circuit 52 modifies the resistance value between the third terminal and the fourth terminal by changing the number of series-connected stages of the current-voltage converters 42 between the third terminal and the fourth terminal. The correction voltage selecting circuit 52 includes n number of switches SW2 (1) to SW2 (n). The n number of switches SW2 (1) to SW2 (n) are collectively denoted by a switch SW2 when not particularly distinguished from one another.

The n number of switches SW2 (1) to SW2 (n) are provided for the n number of current-voltage converters 42, respectively, and each of these switches is used to create electrical conduction and an electrical disconnect between both terminals of corresponding one of the current-voltage converters 42.

In other words, one current-voltage converter 42 and one switch SW2 are connected in parallel, which form one set, and the n number of the sets each having one current-voltage converter 42 and one switch SW2 are connected.

Opening and closing of the n number of switches SW2 (1) to SW2 (n) are controlled by n-bit variable resistive element control signals regn [n:1].

Operations of the operational amplifier circuit 122A configured as above shall be described below.

The variable resistive element 21 receives the variable resistive element control signals regp [n:1], by which opening and closing of the n number of switches SW1 (1) to SW1 (n) are controlled.

Likewise, the variable resistive element 22 receives the variable resistive element control signals regn [n:1], by which opening and closing of the n number of switches SW2 (1) to SW2 (n) are controlled.

These variable resistive element control signals regp [n:1] and variable resistive element control signals regn [n:1] are inputted from, for example, another circuit (not shown) in the display apparatus 10 or an external device of the display apparatus 10.

The resistance value of a set having one current-voltage converter 41 and one switch SW1 connected in parallel can be considered to be 0Ω where the switch SW1 is turned on, and be a resistance value of the current-voltage converter 41 where the switch SW1 is turned off.

Likewise, the resistance value of a set having one current-voltage converter 42 and one switch SW2 connected in parallel can be considered to be 0Ω where the switch SW2 is turned on, and be a resistance value of the current-voltage converter 42 where the switch SW2 is turned off.

For example, in the case of single-stage series connection of the current-voltage converter 41, that is, where n=1, the resistance value of the variable resistive element 21 is one of two values 0Ω and the resistance value R of the current-voltage converter 41.

Alternatively, in the case of two-stage series connection of the current-voltage converters 41, that is, where n=2, suppose that the resistance values of the two current-voltage converters 41 are R and 2R, then the resistance value of the variable resistive element 21 is one of four values 0Ω, R, twice R, and three times R.

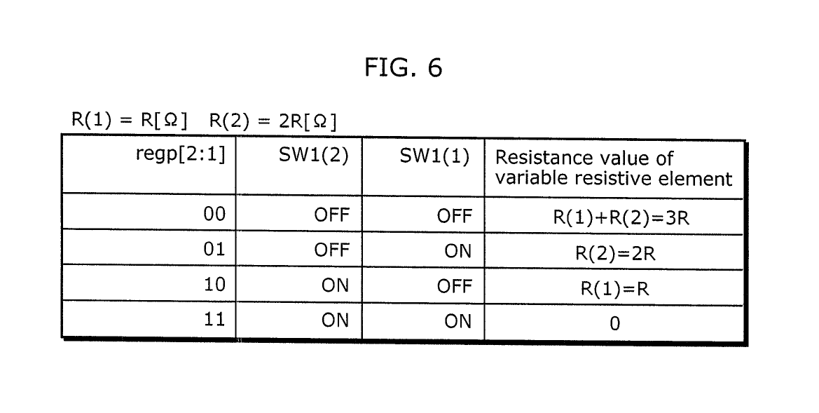

FIG. 6 is a table showing the variable resistive element control signals regp [n:1], ON-OFF states of the switches SW1 (1) to SW (n), and the resistance values of the variable resistive element 21, where n=2.

It is to be noted that the resistance values of the variable resistive element 22 will be the same as those of the variable resistive element 21.

In the operational amplifier circuit 122A, the current source transistor 102 lets a current Ir flow, thereby causing a current Ip to flow through the variable resistive element 21 as well as causing a current In to flow through the variable resistive element 22.

According to the resistance value of the variable resistive element 21 and the current Ip flowing through the variable resistive element 21, a voltage difference ΔVp occurs between the source of the differential transistor 100 on the non-inverting input and the node N1.

Likewise, according to the resistance value of the variable resistive element 22 and the current In flowing though the variable resistive element 22, a voltage difference ΔVn occurs between the source of the differential transistor 101 on the inverting input and the node N1.

The following shall describe the principle that the output voltage variation is reduced when the ΔVn and ΔVp occur.

Firstly, in the operational amplifier circuit 222 shown in FIG. 4, with a voltage Vin applied to the non-inverting input terminal, the output voltage Vout of the operational amplifier circuit 222 is expressed by the following equation (1):

Vout=(Vin−Vp)+Vn (1)

Note that Vp is a sum of a threshold voltage of the differential transistor 100 and an overdrive voltage of the differential transistor 100, and Vn is a sum of a threshold voltage of the differential transistor 101 and an overdrive voltage of the differential transistor 101.

With equal Vp and Vn which result in Vout=Vin, there should be no output voltage variation. However, Vp and Vn will not be equal due to variation inherent in the manufacturing process. This means that output voltage variation arises.

Meanwhile, the output voltage Vout of the operational amplifier circuit 122A according to the first embodiment of the present invention, shown in FIG. 5, is expressed by the following equation (2):

Vout=(Vin−(Vp+ΔVp))+(Vn+ΔVn) (2)

As indicated by the equation (2), the operational amplifier circuit 122A is capable of reducing the output voltage variation by adjusting ΔVp and ΔVn even when Vp and Vn are not equal due to variation inherent in the manufacturing process.

This means that Vout=Vin can be obtained by adjusting ΔVp and ΔVn so as to satisfy Vp+ΔVp=Vn+ΔVn. Thus, the operational amplifier circuit 122A according to the first embodiment of the present invention is capable of reducing the output voltage variation close to 0V.

As an adjusting method for ΔVp and ΔVn, when such output voltage variation arises that the output voltage Vout is higher than the voltage Vin, adjustment is made with the relationship ΔVp>ΔVn maintained, thereby reducing the output voltage variation close to 0 V.

In contrast, when such output voltage variation arises that the output voltage Vout is lower than the voltage Vin, adjustment is made with the relationship ΔVn>ΔVp maintained, thereby reducing the output voltage variation close to 0 V.

One example of the adjusting method for reducing the output voltage variation in the operational amplifier circuit 122A shall be described below.

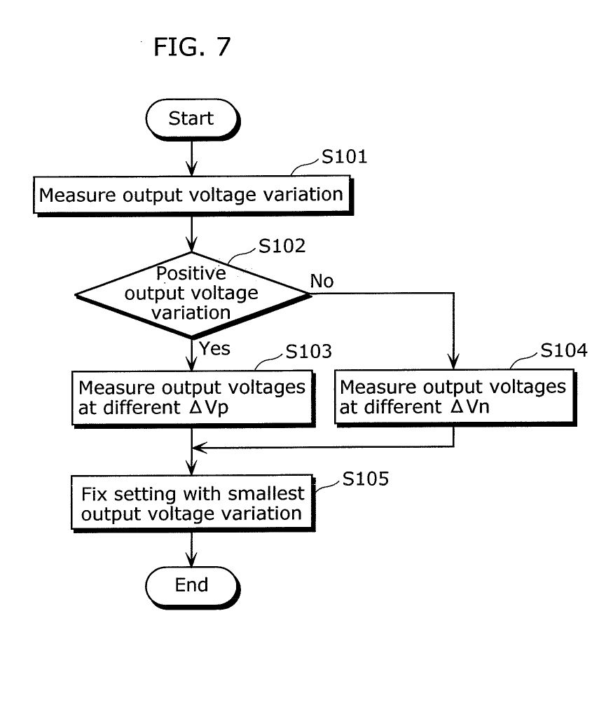

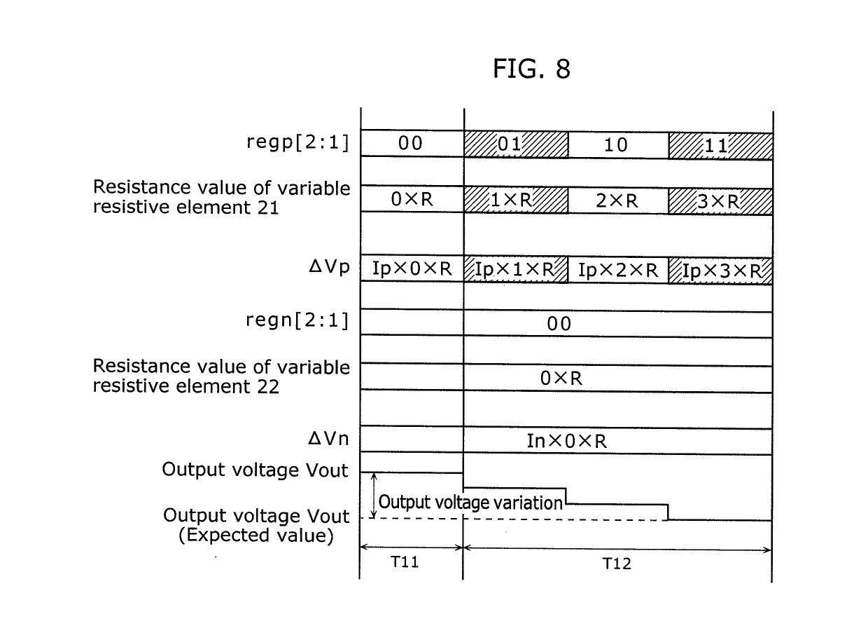

FIG. 7 is a flowchart of this adjusting method. FIG. 8 is a timing chart of this adjusting method. Note that hereinbelow, the adjusting method is explained using an example where n=2.

Here, in FIG. 8, regp [2:1] denotes a control signal for changing the resistance value of the variable resistive element 21, and regn [2:1] denotes a control signal for changing the resistance value of the variable resistive element 22.

FIG. 8 is based on the assumption that positive output voltage variation arises. Note that ΔVp denotes a voltage difference occurring between both ends of the variable resistive element 21, and ΔVn represents a voltage difference occurring between both terminals of the variable resistive element 22.

The adjusting method described below is carried out by an external adjusting device of the display apparatus 10. It is to be noted that part or all of this adjusting method may be carried out by another circuit (not shown) in the display apparatus 10. Moreover, a user who operates the above adjusting device may perform part of this adjusting method.

Firstly, the adjusting device measures the output voltage variation of the operational amplifier circuit 122A with no output voltage variation correction applied (S101).

To be specific, in a period T11, the adjusting device sets both regp [2:1] and regn [2:1] at “00”. This makes both the resistance values of the variable resistive elements 21, 22 be 0Ω. That is, electricity conducts between the node N1 and the source of the differential transistor 100, and electricity conducts between the connection pint N1 and the source of the differential transistor 101. By doing so, ΔVp is determined as Iₚ×0×R≈0 V, and ΔVn is determined as Iₙ×0×R≈0 V.

In this state, the adjusting device measures the output voltage Vout of the operational amplifier circuit 122A.

Next, the adjusting device determines whether there arises positive output voltage variation or negative output voltage variation (S102). In other words, the adjusting device determines whether the measured output voltage Vout is higher or lower than an expected value.

It is to be noted that, when the measured output voltage Vout is equal to the expected value or when a difference between the measured output voltage Vout and the expected value is equal to or smaller than a predetermined value, the adjusting device determines that there is no need for adjustment because the output voltage variation is equal to or smaller than the predetermined value, and therefore does not make the following adjustment.

In this example, suppose that, as shown in FIG. 8, the positive output voltage variation arises.

In the case of the positive output voltage variation (YES in Step S102), the adjusting device changes ΔVp and measures the output voltages Vout at different ΔVp (S103).

To be specific, the adjusting device changes regp [2:1] to “01”, “10”, and “11” sequentially with regn [2:1] fixed at “00” during a period T12. This makes ΔVn fixed at Iₙ×0×R≈0 V as the resistance value of the variable resistive element 22 is fixed at 0Ω. Further, in accordance with regp [2:1], the resistance value of the variable resistive element 21 changes and thus, ΔVp changes.

To be specific, as shown in FIG. 8, ΔVp becomes larger as the settings of regp [2:1] sequentially change to “01”, “10”, and “11”. This causes the output voltage Vout to be closer to the expected value. That is, the output voltage variation becomes reduced.

Next, the adjusting device determines, among the settings of regp [2:1], a setting at which the output voltage variation is the smallest. Moreover, the adjusting device fixes as a corrected setting the setting of regp [2:1] at which the output voltage variation is the smallest (S105). To be specific, at a time point when the output voltage variation becomes the smallest, the adjusting device stops data increment of regp [2:1] and fixes such data of regp [2:1].

In the example shown in FIG. 8, the setting at which the output voltage variation is the smallest is regp [2:1]=“11” with regn [2:1]=“00”. In this case, Vout≈Vin (Vp+ΔVp≈Vn+ΔVn) is satisfied. The output voltage variation can be thus reduced close to 0 V.

Also in the case where negative output voltage variation arises (No in Step S102), the output voltage can be reduced close to 0 V in the same manner by increasing the resistance value of the variable resistive element 22. To be specific, the adjusting device changes ΔVn and measures the output voltages Vout at different ΔVn (S104). Next, the adjusting device determines, among the settings of regn [2:1], a setting at which the output voltage variation is the smallest. Moreover, the adjusting device fixes as a corrected setting the setting of regn [2:1] at which the output voltage variation is the smallest (S105).

As described above, the operational amplifier circuit 122A according to the first embodiment of the present invention is capable of reducing both positive and negative output voltage variation by generating ΔVn and ΔVp with use of the two variable resistive elements 21, 22.

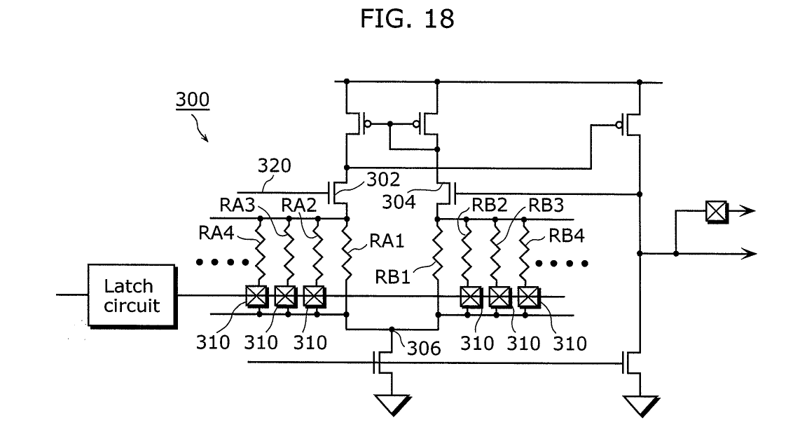

Moreover, the operational amplifier circuit 122A according to the first embodiment of the present invention can be smaller in circuit area than the conventional output circuit 300 shown in FIG. 18.

Specifically, in order to make adjustment intervals equal in the conventional output circuit 300, the switches 310 need to be turned on and off one by one. For example, the conventional output circuit 300 requires 16 resistor-switch sets to enable 16-stage output voltage adjustments.

In contrast, the operational amplifier circuit 122A according to the first embodiment of the present invention only requires four resistor-switch sets to enable the 16-stage output voltage adjustments even at equal adjustment intervals. Thus, the operational amplifier circuit 122A according to the first embodiment of the present invention can be smaller in circuit area than the conventional output circuit.

For smaller circuit area, the conventional output circuit 300 can also make the 16-stage output voltage adjustments with four resistor-switch sets by turning on multiple switches 310 simultaneously instead of turning on the switches 310 one by one. However, in this adjusting method, it is difficult to equalize the intervals among total resistance values of parallel-connected resistors. Accordingly, the output voltage is adjusted with respect to the theoretical value at short intervals in some cases and at long intervals in other cases; there is a problem that variation arises in the adjustment itself.

In contrast, the operational amplifier circuit 122A according to the first embodiment of the present invention is capable of adjusting the 16-stage output voltage at equal intervals, with the four resistor-switch sets.

Furthermore, suppose the operational amplifier circuit 122A according to the first embodiment of the present invention and the conventional output circuit 300 have the same output voltage range to be adjusted by using the same four resistor-switch sets, then the operational amplifier circuit 122A according to the first embodiment of the present invention can be smaller in circuit area than the conventional output circuit 300. This is because this adjustment range is determined according to the maximum possible resistance value of the variable resistive element. The conventional output circuit 300 therefore needs to set one of its resistors which has the largest resistance value, to have the above maximum possible resistance value. On the other hand, in the operational amplifier circuit 122A according to the first embodiment of the present invention, the sum of four resistance values needs to be set to the above maximum possible resistance value. The sum of the four resistance values in the operational amplifier circuit 122A according to the first embodiment of the present invention is thus smaller than the sum of four resistance values in the output circuit 300. Consequently, the operational amplifier circuit 122A according to the first embodiment of the present invention can be smaller in circuit area than the conventional output circuit 300.

The operational amplifier circuit 122A according to the first embodiment of the present invention is thus capable of reducing the output voltage variation with less increase in circuit area.

Although the first embodiment of the invention is described herein by citing the operational amplifier circuit 122A, which has the two variable resistive elements, i.e., the variable resistive element 21 and the variable resistive element 22, the operational amplifier circuit 122A may only have either the variable resistive element 21 or the variable resistive element 22 to reduce either positive or negative output voltage variation. With this configuration, the area of the operational amplifier circuit 122A can be reduced.

### Second Embodiment

In the second embodiment of the present invention, an operational amplifier circuit 122B, which is another example of the operational amplifier circuit 122 shown in FIG. 2, will be explained.

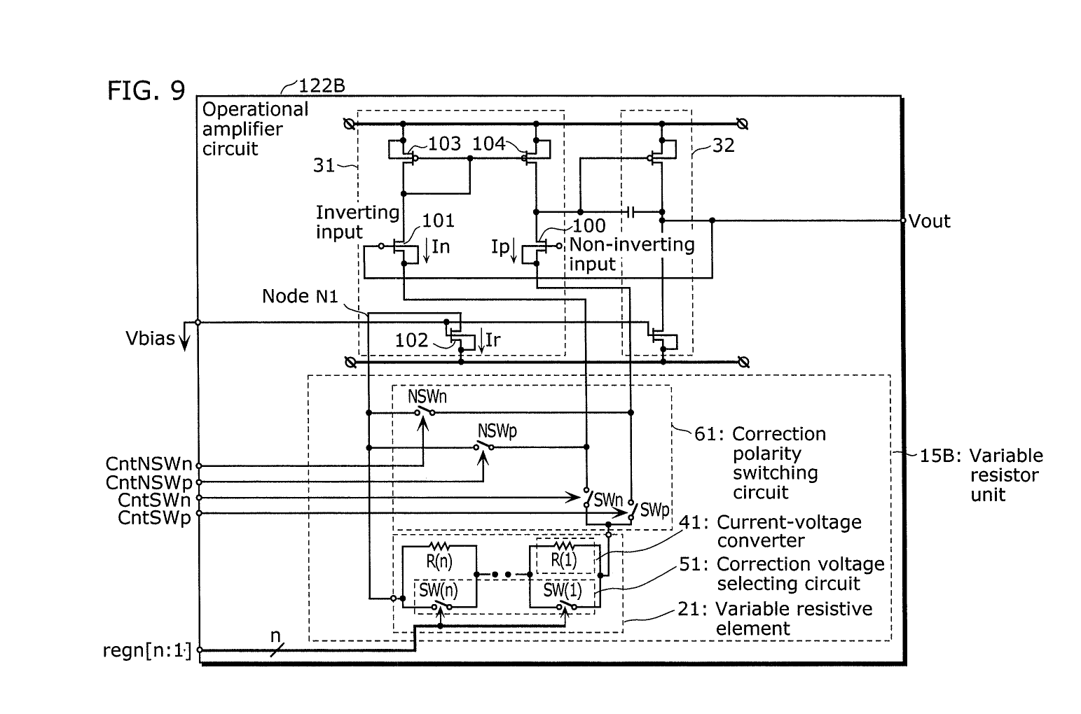

FIG. 9 is a circuit diagram showing the operational amplifier circuit 122B according to the second embodiment of the present invention. It is to be noted that the same numerals are used in FIG. 9 and the description to refer to the same or like elements as those shown in FIG. 5, and explanation thereof will be omitted.

The operational amplifier circuit 122B shown in FIG. 9 is formed by replacing the variable resistor unit 15A of the operational amplifier circuit 122A shown in FIG. 5 with a variable resistor unit 15B. The variable resistor unit 15B includes a variable resistive element 21 and a correction polarity switching circuit 61.

The variable resistive element 21 is connected between (i) the sources of the differential transistor 100 on the non-inverting input and the differential transistor 101 on the inverting input and (ii) the drain of the current source transistor 102. To be specific, the variable resistive element 21 has its first terminal connected to the correction polarity switching circuit 61 and its second terminal connected to the node N1 (the drain of the current source transistor 102). The configuration of the variable resistive element 21 is the same as that of the variable resistive element 21 shown in FIG. 5.

The correction polarity switching circuit 61 switches between the first mode and the second mode. In the first mode, the variable resistive element 21 is connected between the source of the differential transistor 100 on the non-inverting input and the node N1, but is not connected between the source of the differential transistor 101 on the inverting input and the node N1. In the second mode, the variable resistive element 21 is connected between the source of the differential transistor 101 on the inverting input and the node N1, but is not connected between the source of the differential transistor 100 on the non-inverting input and the node N1.

To be specific, in the first mode, the correction polarity switching circuit 61 connects the first terminal of the variable resistive element 21 with the source of the differential transistor 100 on the non-inverting input and electrically shorts the source of the differential transistor 101 on the inverting input to the drain of the current source transistor 102. In the second mode, the correction polarity switching circuit 61 connects the first terminal of the variable resistive element 21 with the source of the differential transistor 101 on the inverting input and electrically shorts the source of the differential transistor 100 on the non-inverting input to the drain of the current source transistor 102.

This correction polarity switching circuit 61 includes a switch SWn, a switch SWp, a switch NSWn, and a switch NSWp.

The switch SWp is connected between the first terminal of the variable resistive element 21 and the source of the differential transistor 100, and opening and closing of the switch SWp are controlled by a control signal CntSWp. This switch SWp is used to create electrical conduction between the source of the differential transistor 100 and the first terminal of the variable resistive element 21 with the correction polarity switching circuit 61 set in the first mode and used to create an electrical disconnect between the source of the differential transistor 100 and the first terminal of the variable resistive element 21 with the correction polarity switching circuit 61 set in the second mode.

The switch SWn is connected between the first terminal of the variable resistive element 21 and the source of the differential transistor 101, and opening and closing the switch SWn is controlled by a control signal CntSWn. This switch SWn is used to create electrical conduction between the source of the differential transistor 101 and the first terminal of the variable resistive element 21 with the correction polarity switching circuit 61 set in the second mode and used to create an electrical disconnect between the source of the differential transistor 101 and the first terminal of the variable resistive element 21 with the correction polarity switching circuit 61 set in the first mode.

The switch NSWp is connected between the node N1 and the source of the differential transistor 101, and opening and closing the switch NSWp are controlled by a control signal CntNSWp. This switch NSWp is used to create electrical conduction between the source of the differential transistor 101 on the inverting input and the node N1 with the correction polarity switching circuit 61 set in the first mode and used to create an electrical disconnect between the source of the differential transistor 101 on the inverting input and the node N1 with the correction polarity switching circuit 61 set in the second mode.

The switch NSWn is connected between the node N1 and the source of the differential transistor 100, and opening and closing of the switch NSWn are controlled by a control signal CntNSWn. This switch NSWn is used to create electrical conduction between the source of the differential transistor 100 on the non-inverting input and the node N1 with the correction polarity switching circuit 61 set in the second mode and used to create an electrical disconnect between the source of the differential transistor 100 on the non-inverting input and the node N1 with the correction polarity switching circuit 61 set in the first mode.

The control signal CntSWn, the control signal CntSWp, the control signal CntNSWn, and the control signal CntNSWp are inputted from, for example, another circuit (not shown) in the display apparatus 10 or an external device of the display apparatus 10.

Operations of the operational amplifier circuit 122B configured as above according to the second embodiment of the present invention shall be described below.

The variable resistive element 21 receives the variable resistive element control signals regp [n:1], by which opening and closing of the n number of switches SW1 (1) to SW1 (n) are controlled.

With the switch SW1 turned on, the total resistance value of the sets each having one current-voltage converter 41 and one switch SW1, which are connected in parallel, is ideally 0Ω. On the other hand, with the switch SW1 turned off, the total resistance value of the sets each having one current-voltage converter 41 and one switch SW1, which are connected in parallel, is ideally a resistance value of the current-voltage converter 41.

For example, in the case of single-stage series connection of the current-voltage converter 41, that is, where n=1, the resistance value of the variable resistive element 21 is one of two values 0Ω and the resistance value R of the current-voltage converter 41.

Alternatively, in the case of two-stage series connection of the current-voltage converters 41, that is, where n=2, suppose that the resistance values of the two current-voltage converters 41 are R and 2R, then the resistance value of the variable resistive element 21 is one of four values 0Ω, R, twice R, and three times R.

In the operational amplifier circuit 122B, the current source transistor 102 lets a current Ir flow, thereby causing a current Ip to flow through the differential transistor 100 on the non-inverting input as well as causing a current In to flow through the differential transistor 101 on the inverting input.

The correction polarity switching circuit 61 is used to switch the current which is to flow through the variable resistive element 21, between the current Ip and the current In, depending on which control signal CntSWp, CntSWn, Cnt NSWp, or CntNSWn the correction polarity switching circuit 61 receives.

To be specific, in the case where the output voltage Vout is higher than the non-inverting input voltage, that is, where positive output voltage variation arises, the switch SWp is turned on according to the control signal CntSWp while the switch SWn is turned off according to the control signal CntSWn. In this case, the switch NSWp is turned on according to the control signal CntNSWp while the switch NSWn is turned off according to the control signal CntNSWn. The correction polarity switching circuit 61 thus sets the first mode to cause the current Ip to flow through the variable resistive element 21.

This means that in the first mode, the current Ip causes the voltage difference ΔVp, whose value depends on the resistance value of the variable resistive element 21, to occur between the source of the differential transistor 100 on the non-inverting input and the node N1.

On the other hand, in the case where the output voltage Vout is lower than the non-inverting input voltage, that is, where negative output voltage variation arises, the switch SWn is turned on according to the control signal CntSWn while the switch SWp is turned off according to the control signal CntSWp. In this case, the switch NSWp is turned off according to the control signal CntNSWp while the switch NSWn is turned on according to the control signal CntNSWn. The correction polarity switching circuit 61 thus sets the second mode to cause the current In to flow through the variable resistive element 21.

This means that in the second mode, the current In causes the voltage difference ΔVn, whose value depends on the resistance value of the variable resistive element 21, to occur between the source of the differential transistor 101 on the inverting input and the node N1.

The same explanation about capability of reducing the output voltage variation by generating ΔVn and ΔVp as made in the first embodiment applies to the present embodiment.

One example of the adjusting method for reducing the output voltage variation in the operational amplifier circuit 122B shall be described below.

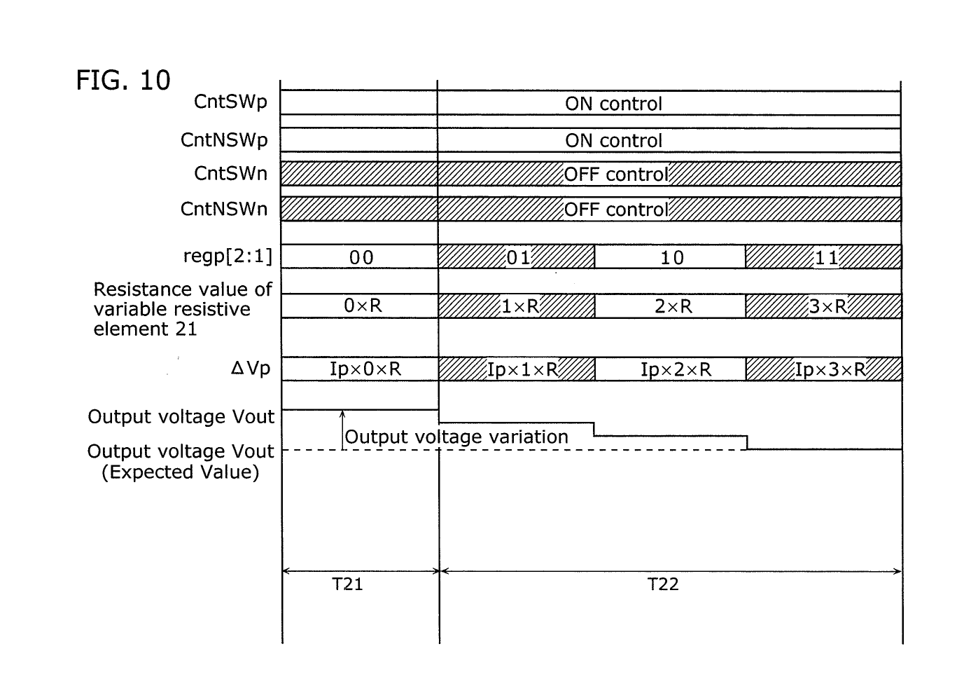

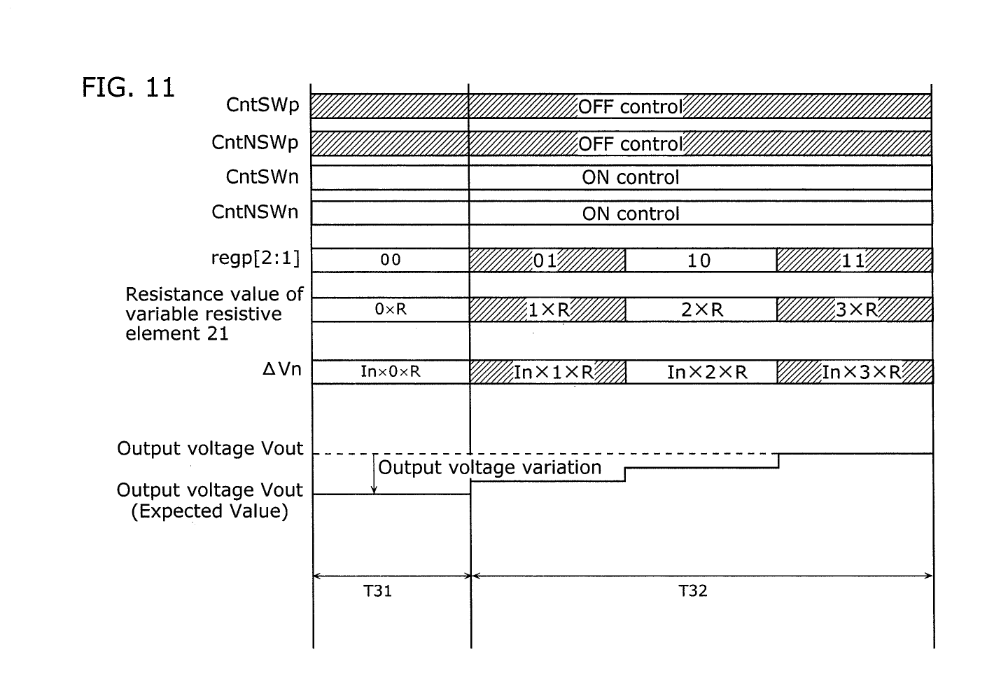

FIGS. 10 and 11 each show a timing chart of this adjusting method.

Here, in FIGS. 10 and 11, regp [n:1] denotes a control signal for changing the resistance value of the variable resistive element 21, and as explained above, CntSWp, CntSWn, CntNSWn, and CntNSWp denote the control signals inputted to the correction polarity switching circuit 61. The symbols ΔVp and ΔVn each denote a voltage difference occurring between the both terminals of the variable resistive element 21.

It is to be noted that FIG. 10 is based on the assumption that positive output voltage variation arises where n=2 in regp [n:1], and FIG. 11 is based on the assumption that negative output voltage variation arises where n=2 in regp [n:1].

The general flow of this adjusting method is the same as shown in FIG. 7.

Firstly, the adjusting device measures the output voltage variation of the operational amplifier circuit 122B with no output voltage variation correction applied (S101).

In measuring the output voltage variation, the adjusting device (1) turns on both the switches NSWn and NSWp or (2) sets regp [2:1] at “00”, to create electrical conduction between the node N1 and the source of the differential transistor 100 and create electrical conduction between the node N1 and the source of the differential transistor 101.

Next, the adjusting device determines whether there arises positive output voltage variation or negative output voltage variation (S102).

The following explanation describes the situation where the positive output voltage variation arises (Yes in S102), which is shown in FIG. 10.

As shown in FIG. 10, the control signals CntSWp and CntNSWp are logics to turn the corresponding switches on, and the control signals CntSWn and CntNSWn are logics to turn the corresponding switches off. By doing so, the first mode is set in which the current Ip flows through the variable resistive element 21.

During a period T21 in FIG. 10, a resistance value of the variable resistive element 21 is 0Ω and ΔVp is Ip×0×R≈0 V. With this set state, large output voltage variation will arise.

In a period T22 in FIG. 10, the adjusting device changes ΔVp and measures the output voltages Vout at different ΔVp (S103). To be specific, the resistance value of the variable resistive element 21 varies in accordance with regp [2:1].

As shown in FIG. 10, ΔVp becomes larger as the settings of regp [2:1] sequentially change to “01”, “10”, and “11”.

Next, the adjusting device determines, among the settings of regp [2:1], a setting at which the output voltage variation is the smallest. Moreover, the adjusting device fixes as a corrected setting the setting of regp [2:1] at which the output voltage variation is the smallest (S105).

In the example shown in FIG. 10, the setting at which the output voltage variation is the smallest is regp [2:1]=“11”. In this case, Vout≈Vin (Vp+ΔVp≈Vn+ΔVn) is satisfied. That is, the output voltage variation can be reduced close to 0 V.

Next, the situation where the negative output voltage variation arises (No in S102), which is shown in FIG. 11, will be explained.

As shown in FIG. 11, the control signals CntSWp and CntNSWp are logics to turn the corresponding switches off, and the control signals CntSWn and CntNSWn are logics to turn the corresponding switches on. By doing so, the second mode is set in which the current In flows through the variable resistive element 21.

During a period T31 in FIG. 11, a resistance value of the variable resistive element 21 is 0Ω and ΔVn is In×0×R≈0 V. With this set state, large output voltage variation will arise as in the case of the conventional operational amplifier circuit 222.

In a period T32 in FIG. 11, the adjusting device changes ΔVn and measures the output voltages Vout at different ΔVn (S104). To be specific, the resistance value of the variable resistive element 21 varies in accordance with regp [2:1].

As shown in FIG. 11, the output voltage ΔVn becomes closer to the expected value as the settings of regp [2:1] sequentially change to “01”, “10”, and “11”.

Next, the adjusting device determines, among the settings of regp [2:1], a setting at which the output voltage variation is the smallest. Moreover, the adjusting device fixes as a corrected setting the setting of regp [2:1] at which the output voltage variation is the smallest (S105).

In the example shown in FIG. 11, the setting at which the output voltage variation is the smallest is a setting at which regp [2:1]=“11”. In this case, Vout≈Vin (Vp+ΔVp≈Vn+ΔVn) is satisfied. That is, the output voltage variation can be reduced close to 0 V.

The operational amplifier circuit 122B according to the second embodiment of the present invention is thus capable of reducing both the positive and negative output voltage variation with less increase in circuit area, as in the first embodiment.

Moreover, the operational amplifier circuit 122B, which includes the correction polarity switching circuit 61, is thereby capable of generating ΔVn and ΔVp with one variable resistance element 21. This allows the operational amplifier circuit 122B to have a smaller circuit area than the operational amplifier circuit 122A according to the first embodiment.

### Third Embodiment

In the third embodiment of the present invention, an operational amplifier circuit 122C, which is another example of the operational amplifier circuit 122 shown in FIG. 2, will be explained.

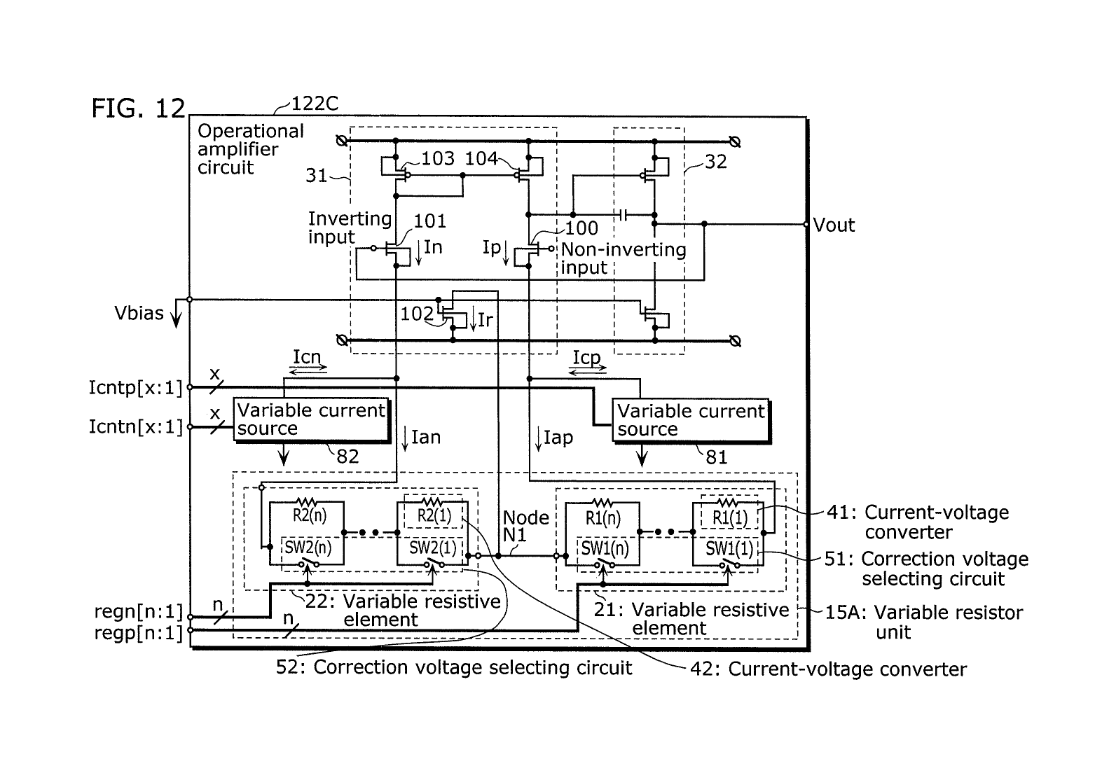

FIG. 12 is a circuit diagram showing an operational amplifier circuit 122C according to the third embodiment of the present invention. It is to be noted that the same numerals are used in FIG. 12 and the description to refer to the same or like elements as those shown in FIG. 5, and explanation thereof will be omitted.

The operational amplifier circuit 122C shown in FIG. 12 has variable current sources 81, 82 in addition to the configuration of the operational amplifier circuit 122A shown in FIG. 5.

The variable current source 81 is connected between the source of the differential transistor 100 on the non-inverting input and a line to which a bias voltage is applied, to supply a positive or negative current Icp to the source of the differential transistor 100 on the non-inverting input. Moreover, the variable current source 81 selectively supplies a current having one of x-stage current values to the source of the differential transistor 100. This means that a current value of the current Icp generated by the variable current source 81 varies in x stages. This current value is controlled by a variable current source control signal Icntp [x:1].

The variable current source 82 is connected between the source of the differential transistor 101 on the inverting input and a line to which a bias voltage is applied, to supply a positive or negative current Icn to the source of the differential transistor 101 on the inverting input. Moreover, the variable current source 82 selectively supplies a current having one of x-stage current values to the source of the differential transistor 101. This means that a current value of the current Icn generated by the variable current source 82 varies in x stages. This current value is controlled by a variable current source control signal Icntn [x:1].

The variable current source signal Icntp [x:1] and the variable current source signal Icntn [x:1] are inputted from, for example, another circuit (not shown) in the display apparatus 10 or an external device of the display apparatus 10.

Operations of the operational amplifier circuit 122C configured as above according to the third embodiment of the present invention shall be described below.

The variable resistive element 21 receives the variable resistive element control signals regp [n:1], by which shoring and opening of the n number of switches SW1 (1) to SW1 (n) are controlled.

Likewise, the variable resistive element 22 receives the variable resistive element control signals regn [n:1], by which opening and closing of the n number of switches SW2 (1) to SW2 (n) are controlled.

With the switch SW1 turned on, the total resistance value of the sets each having one current-voltage converter 41 and one switch SW1, which are connected in parallel, is ideally 0Ω. On the other hand, with the switch SW1 turned off, the total resistance value of the sets each having one current-voltage converter 41 and one switch SW1, which are connected in parallel, is ideally a resistance value of the current-voltage converter 41.

Likewise, with the switch SW2 turned on, the total resistance value of the sets each having one current-voltage converter 42 and one switch SW2, which are connected in parallel, is ideally 0Ω. On the other hand, with the switch SW2 turned off, the total resistance value of the sets each having one current-voltage converter 42 and one switch SW2, which are connected in parallel, is ideally a resistance value of the current-voltage converter 42.

For example, in the case of single-stage series connection of the current-voltage converter 41, that is, where n=1, the resistance value of the variable resistive element 21 is one of two values 0Ω and the resistance value R of the current-voltage converter 41.

Alternatively, in the case of two-stage series connection of the current-voltage converters 41, that is, where n=2, suppose that the resistance values of the two current-voltage converters 41 are R and 2R, then the resistance value of the variable resistive element 21 is one of four values 0Ω, R, twice R, and three times R.

In the operational amplifier circuit 122C, the current source transistor 102 lets a current Ir flow, thereby causing a current Ip to flow through the differential transistor 100 on the non-inverting input as well as causing a current In to flow through the differential transistor 101 on the inverting input.

In this case, the current which flows through the variable resistive element 21 is a current Iap that is combination of the current Ip and the current Icp generated by the variable current source 81 or is an Icp-subtracted current from the current Ip.

Likewise, the current which flows through the variable resistive element 22 is a current Ian that is combination of the current In and the current Icn generated by the variable current source 82 or is Icn-subtracted current from the current In.

According to the resistance value of the variable resistive element 21 and the current Iap flowing through the variable resistive element 21, a voltage difference ΔVp occurs. This voltage difference ΔVp can be modified by changing the variable resistive element control signal regp [n:1] and the variable current source control signal Icntp [x:1].

Likewise, according to the resistance value of the variable resistive element 22 and the current Ian flowing through the variable resistive element 22, a voltage difference ΔVn occurs. This voltage difference ΔVn can be modified by changing the variable resistive element control signal regn [n:1] and the variable current source control signal Icntn [x:1].

The same explanation about capability of reducing the output voltage variation by generating ΔVn and ΔVp as made in the first embodiment applies to the present embodiment.

The operational amplifier circuit 122C according to the third embodiment of the present invention is thus capable of reducing both the positive and negative output voltage variation with less increase in circuit area, as in the first embodiment.

Moreover, the operational amplifier circuit 122C according to the third embodiment of the present invention, which includes the variable current sources 81, 82 in addition to the configuration of the operational amplifier circuit 122A according to the first embodiment, is thereby capable of modifying ΔVn and ΔVp with use of both the variable resistive elements 21, 22 and the variable current sources 81, 82. Accordingly, the operational amplifier circuit 122C according to the third embodiment is capable of dealing with larger output voltage variation than the output voltage variation that can be dealt with by the operational amplifier circuit 122A according to the first embodiment, and is also capable of setting shorter adjustment intervals for the output voltage variation than the adjustment intervals set by the operational amplifier circuit 122A according to the first embodiment.

Furthermore, it is possible that the operational amplifier circuit 122C according to the third embodiment requires a smaller area to provide comparable adjustment range and intervals of the output voltage variation to those of the operational amplifier circuit 122A according to the first embodiment. This downsizing can be achieved by, for example, using one transistor to constitute the variable current sources 81, 82.

Although the third embodiment of the invention is described herein by citing the operational amplifier circuit 122C, which has the two variable resistive elements, i.e., the variable resistive element 21 and the variable resistive element 22, the operational amplifier circuit 122C may only have either the variable resistive element 21 or the variable resistive element 22 to reduce either positive or negative output voltage variation. In this case, the operational amplifier circuit 122C may have only one of the two variable current sources 81, 82, which corresponds to the either positive or negative output voltage variation to be reduced. With this configuration, the area of the operational amplifier circuit 122C can be reduced.

Further, the operational amplifier circuit 122C may have both of the variable resistive elements 21, 22 with only one of the variable current sources 81, 82, or alternatively have only one of the variable resistive elements 21, 22 with both of the variable current sources 81, 82.

In addition, although the above third embodiment of the invention is described herein with the configuration in which the operational amplifier circuit 122A described in the first embodiment further includes the variable current sources 81, 82, the operational amplifier circuit 122B described in the second embodiment may further include the variable current sources 81, 82.

### Fourth Embodiment

In the fourth embodiment of the present invention, an operational amplifier circuit 122D, which is another example of the operational amplifier circuit 122 shown in FIG. 2, will be explained.

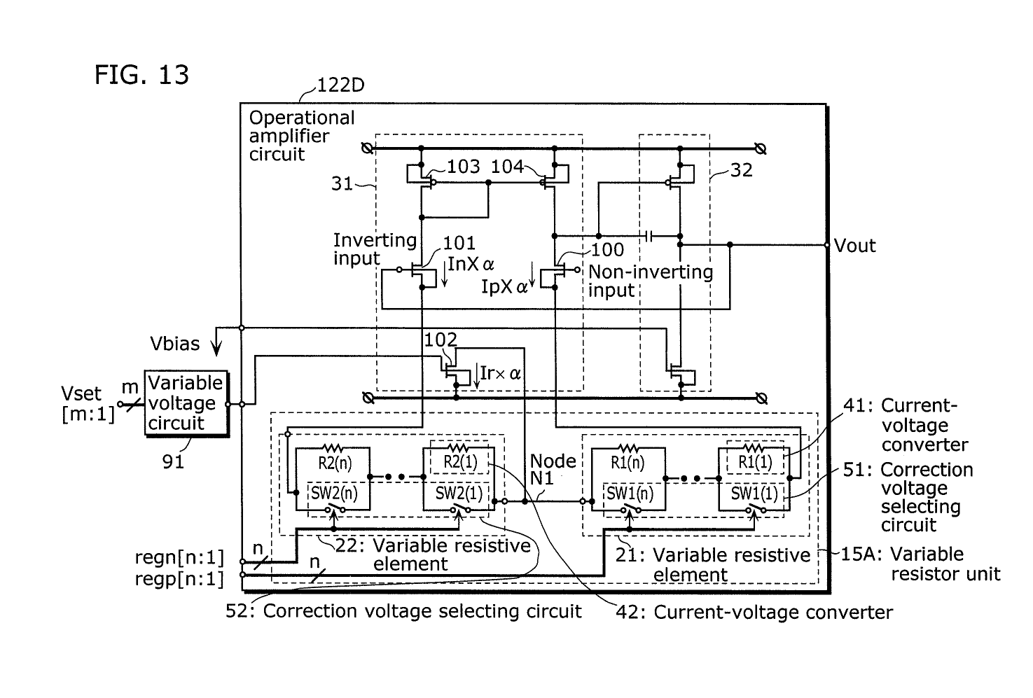

FIG. 13 is a circuit diagram showing an operational amplifier circuit 122D according to the fourth embodiment of the present invention. It is to be noted that the same numerals are used in FIG. 13 and the description to refer to the same or like elements as shown in FIG. 5, and explanation thereof will be omitted.

The operational amplifier circuit 122D shown in FIG. 13 has a variable voltage circuit 91 in addition to the configuration of the operational amplifier circuit 122A shown in FIG. 5

The variable voltage circuit 91 controls a gate voltage of the current source transistor 102. This variable voltage circuit 91 outputs to the gate of the current source transistor 102 a voltage having one of voltage values which is selected from among m levels according to a variable voltage circuit control signal Vset [m:1].

The variable voltage circuit control signal Vset [m:1] is inputted from, for example, another circuit (not shown) in the display apparatus 10 or an external device of the display apparatus 10.

Operations of the operational amplifier circuit 122D configured as above according to the fourth embodiment of the present invention shall be described below.

The variable resistive element 21 receives the variable resistive element control signals regp [n:1], by which opening and closing of the n number of switches SW1 (1) to SW1 (n) are controlled.

Likewise, the variable resistive element 22 receives the variable resistive element control signals regn [n:1], by which opening and closing of the n number of switches SW2 (1) to SW2 (n) are controlled.

With the switch SW1 turned on, the total resistance value of the sets each having one current-voltage converter 41 and one switch SW1, which are connected in parallel, is ideally 0Ω. On the other hand, with the switch SW1 turned off, the total resistance value of the sets each having one current-voltage converter 41 and one switch SW1, which are connected in parallel, is ideally a resistance value of the current-voltage converter 41.

Likewise, with the switch SW2 turned on, the total resistance value of the sets each having one current-voltage converter 42 and one switch SW2, which are connected in parallel, is ideally 0Ω. On the other hand, with the switch SW2 turned off, the total resistance value of the sets each having one current-voltage converter 42 and one switch SW2, which are connected in parallel, is ideally a resistance value of the current-voltage converter 42.

For example, in the case of single-stage series connection of the current-voltage converter 41, that is, where n=1, the resistance value of the variable resistive element 21 is one of two values 0Ω and the resistance value R of the current-voltage converter 41.

Alternatively, in the case of two-stage series connection of the current-voltage converters 41, that is, where n=2, suppose the resistance values of the two current-voltage converters 41 are R and 2R, then the resistance value of the variable resistive element 21 is one of four values 0Ω, R, twice R, and three times R.

According to the variable voltage circuit control signal Vset [n:1], the variable voltage circuit 91 modifies the gate voltage of the current source transistor 102. This allows for a change of the current Ir×a, which flows through the current source transistor 102.

For example, when the current Ir is multiplied by a, it is ideal that the current Ip×a flows through the differential transistor 100 on the non-inverting input and the current In×a flows through the differential transistor 101 on the inverting input.

This means that it is possible to generate any voltage difference ΔVp×a between the source of the differential transistor 100 on the non-inverting input and the node N1 by controlling the resistance value of the variable resistive element 21 and the current Ip×a flowing through the variable resistive element 21.

Likewise, it is possible to generate any voltage difference ΔVn×a between the source of the differential transistor 101 on the inverting input and the node N1 by controlling the resistance value of the variable resistive element 22 and the current In×a flowing through the variable resistive element 22.

It is to be noted that the same explanation about capability of reducing the output voltage variation by substitution ΔVn×a=ΔVn and substitution ΔVp×a=ΔVp as made in the first embodiment applies to the present embodiment.

The operational amplifier circuit 122D according to the fourth embodiment of the present invention is thus capable of reducing both the positive and negative output voltage variation with less increase in circuit area, as in the first embodiment.

Moreover, the operational amplifier circuit 122D according to the fourth embodiment of the present invention, in which the gate voltage of the current source transistor 102 can be changed, is thereby capable of modifying the voltage difference ΔVp occurring between the both terminals of the variable resistive elements 21 and the voltage difference ΔVn occurring between the both terminals of the variable resistive elements 22 more delicately than the operational amplifier circuit 122A according to the first embodiment. Furthermore, the operational amplifier circuit 122D according to the fourth embodiment is capable of dealing with larger output voltage variation than the output voltage variation that can be dealt with by the operational amplifier circuit 122A according to the first embodiment.

Although the fourth embodiment of the invention is described herein by citing the operational amplifier circuit 122D, which has the two variable resistive elements, i.e., the variable resistive element 21 and the variable resistive element 22, the operational amplifier circuit 122D may only have either the variable resistive element 21 or the variable resistive element 22 to reduce either positive or negative output voltage variation. With this configuration, the area of the operational amplifier circuit 122D can be reduced.

In addition, although the above fourth embodiment of the invention is described herein with the configuration in which the operational amplifier circuit 122A described in the first embodiment further includes the variable voltage circuit 91, it is also possible that the operational amplifier circuit 122B described in the second embodiment or the operational amplifier circuit 122C described in the third embodiment further includes the variable voltage circuit 91.

It is to be noted that the present invention is not limited to the above first through fourth embodiments, and various modifications thereof, which are of course encompassed by the appended claims, are possible.

For example, although the operational amplifier circuits 122A to 122D, each of which includes an N-channel MOS transistor pair as a differential pair, are illustrated in the first to fourth embodiments of the present invention, the present invention can be applied also to an operational amplifier circuit which includes a P-channel MOS transistor pair as a differential pair.

Furthermore, the operational amplifier circuits 122A to 122D may include the first differential pair, which is the N-channel MOS transistor pair, and the second differential pair, which is the P-channel MOS transistor pair. This means that the present invention can be applied, with the same design idea, to even an operational amplifier circuit which includes multiple differential pairs, such as a rail-to-rail operational amplifier circuit.

The resistance value of the correction voltage selecting circuit 51 (52) has temperature dependence, which is preferably opposite to temperature dependence of the resistance value of the switch SW1 (SW2). With this configuration, temperature-dependent fluctuation in the resistance of the correction voltage selecting circuit 51 (52) can be cancelled out by temperature-dependent fluctuation in the resistance of the switch SW1 (SW2). Consequently, the output voltage variation can be less temperature dependent.

In addition, the variable resistive elements 21, 22 may each have the following configuration without being restricted to aforementioned configurations.

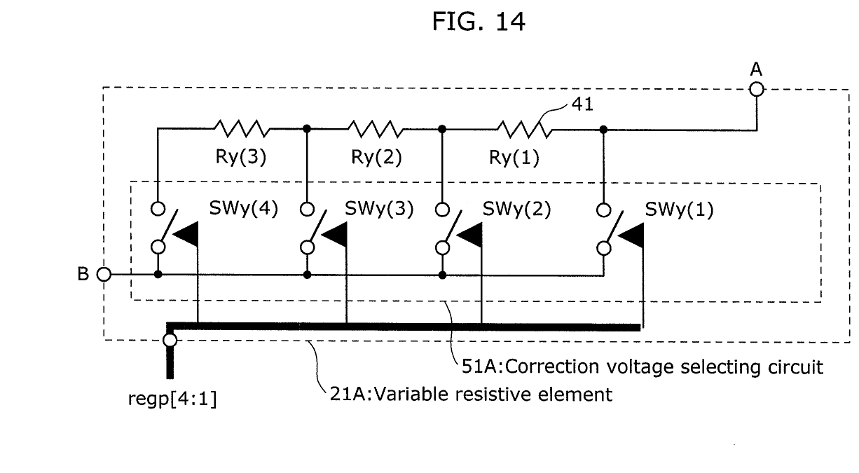

FIG. 14 is a diagram showing a configuration of a variable resistive element 21A, which is another example of the above variable resistive elements 21, 22.

The variable resistive element 21A shown in FIG. 14 includes n−1 number (where n is an integer equal to or greater than 2) of current-voltage converters 41 connected in series, and a correction voltage selecting circuit 51A. It is to be noted that FIG. 14 illustrates an example where n=4.

The current-voltage converters 42 are resistive elements by which a current is converted into a voltage. For example, the n−1 number of the current-voltage converters 41 have equal resistance values.

The correction voltage selecting circuit 51A modifies the resistance value between the first terminal A and the second terminal B by changing the number of series-connected stages of the current-voltage converters 41 between the first terminal A and the second terminal B. The correction voltage selecting circuit 51A includes n number of switches SWy (1) to SWy (n). The n number of switches SWy (1) to SWy (n) are collectively denoted by a switch SWy when not particularly distinguished from one another.

Each of the n number of switches SWy (1) to SWy (n) has a terminal connected to one of a connection node of series connection of the n−1 number of the current voltage converters 41 and both ends of this series connection, and the other terminals connected to the second terminal B. Opening and closing of the n number of switches SWy (1) to SWy (n) are controlled by n-bit variable resistive element control signals regn [n:1].

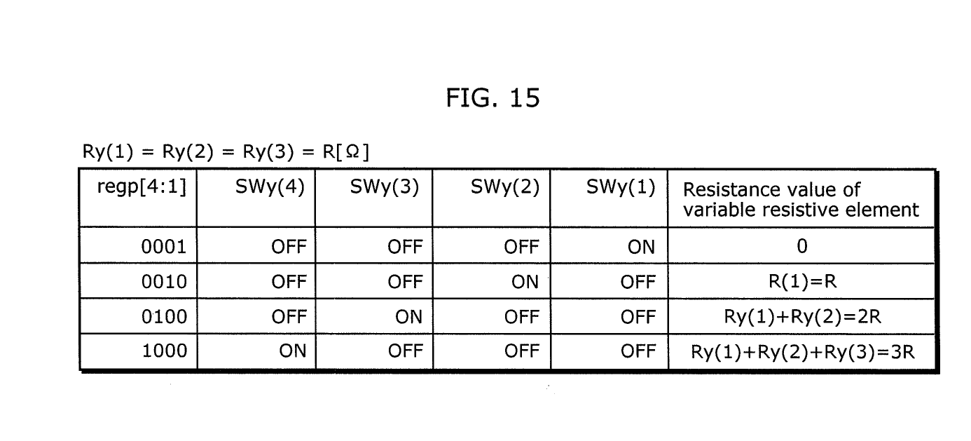

FIG. 15 is a table showing the variable resistive element control signals regp [n:1], ON-OFF states of the switches SWy (1) to SWy (n), and the resistance values of the variable resistive element 21A, where n=4.

As shown in FIG. 15, adjustment intervals can be made equal to one another by setting the three current-voltage converters 41 to have equal resistance values and turning on only one of the four switches SWy (1) to SWy (4).

Furthermore, suppose an operational amplifier circuit which includes the variable resistive element 21A shown in FIG. 15, and the conventional output circuit 300 have the same output voltage range to be adjusted, then the operational amplifier circuit which includes the variable resistive element 21A shown in FIG. 15, can be smaller in circuit area than the conventional output circuit 300. This is because this adjustment range is determined according to the maximum possible resistance value of the variable resistive element. The conventional output circuit 300 therefore needs to set one of its resistors which has the largest resistance value, to the above maximum possible resistance value. On the other hand, in the operational amplifier circuit which includes the variable resistive element 21 shown in FIG. 15, the sum of resistance values of the multiple current-voltage converters 41 needs to be set to the above maximum possible resistance value. Thus, even in the case with the variable resistive element 21A shown in FIG. 15, the circuit area can be smaller than in the conventional output circuit 300, as in the case with the variable resistive elements 21, 22, which are shown in FIG. 5, etc.

It is to be noted that the variable resistive element 21, which is shown in FIG. 5, etc., is more preferable than the variable resistive element 21A, because the variable resistive element 21 requires a smaller area than a area required by the variable resistive element 21A to adjust the output voltage at equal intervals.

Alternatively, the following configuration may also be used, instead of the variable resistive elements 21, 22.

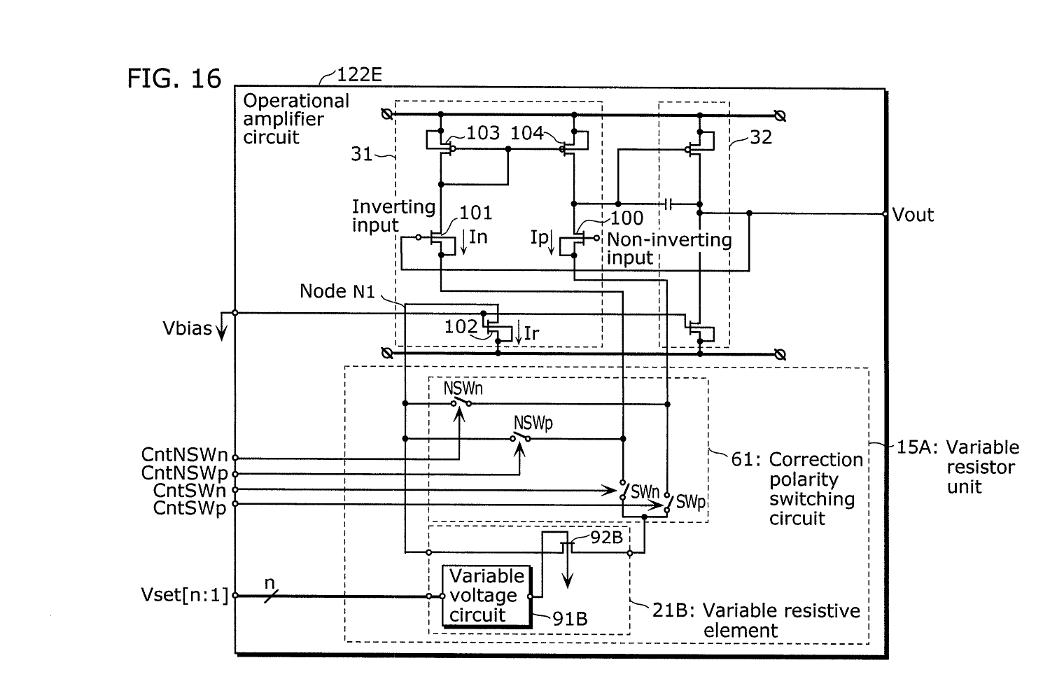

FIG. 16 is a diagram showing a configuration of an operational amplifier circuit 122E including a variable resistive element 21B, which is another example of the above variable resistive elements 21, 22. It is to be noted that the same numerals are used in FIG. 16 and the description to refer to the same or like elements as those shown in FIG. 9.

The operational amplifier circuit 122E shown in FIG. 16 is formed by replacing the variable resistive element 21 of the operational amplifier circuit 122B shown in FIG. 9 with a variable resistive element 21B.

The variable resistive element 21B includes a transistor 92B and a variable voltage circuit 91B.

The transistor 92B has one of its source terminal and drain terminal connected to the first terminal of the variable resistive element 21B, and the other one of its source terminal and drain terminal connected to the second terminal of the variable resistive element 21B. To the transistor 92B, a constant bias voltage is supplied as a substrate voltage.

The variable voltage circuit 91B modifies on-resistance of the transistor 92B by supplying to a gate terminal of the transistor 92B a voltage having one of n-stage voltage values according to a control signal Vset [n:1]. To be specific, the variable voltage circuit 91B modifies the resistance value between the first terminal and the second terminal of the variable resistive element 21B (that is the on-resistance of the transistor 92B) by changing the gate voltage of the transistor 92B.

This configuration allows the variable resistive element to be composed of one transistor and one variable voltage circuit, instead of the multiple resistive element-switch sets, resulting in reduction in area of the variable resistive element.

Alternatively, the following configuration may also be used, instead of the variable resistive elements 21, 22.

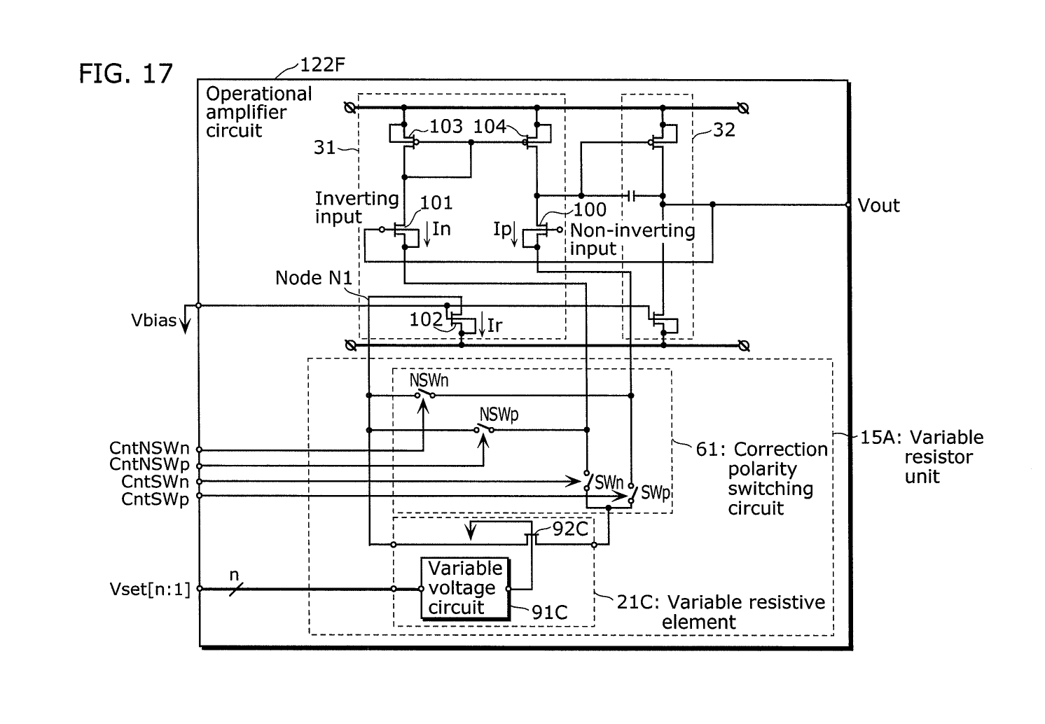

FIG. 17 is a diagram showing a configuration of an operational amplifier circuit 122E including a variable resistive element 21C, which is another example of the above variable resistive elements 21, 22. It is to be noted that the same numerals are used in FIG. 17 and the description to refer to the same or like elements as those shown in FIG. 9.

The operational amplifier circuit 122F shown in FIG. 17 is formed by replacing the variable resistive element 21 of the operational amplifier circuit 122B shown in FIG. 9 with a variable resistive element 21 C.

The variable resistive element 21C includes a transistor 92C and a variable voltage circuit 91C.

The transistor 92C has one of its source terminal and drain terminal connected to the first terminal of the variable resistive element 21C, and the other one of its source terminal and drain terminal connected to the second terminal of the variable resistive element 21C. To a gate terminal of the transistor 92C, a constant bias voltage is applied.

The variable voltage circuit 91C modifies on-resistance of the transistor 92C by supplying to the transistor 92C a voltage having one of n-stage voltage values according to a control signal Vset [n:1]. To be specific, the variable voltage circuit 91C modifies the on-resistance of the transistor 92C by changing a substrate voltage of the transistor 92C in n stages. This causes the variable voltage circuit 91C to modify the resistance value between the first terminal and the second terminal of the variable resistive element 21C (that is the on-resistance of the transistor 92C).

This configuration allows the variable resistive element to be composed of one transistor and one variable voltage circuit, instead of the multiple resistive element-switch sets, resulting in reduction in area of the variable resistive element.

It is to be noted that the variable resistive element 21B shown in FIG. 16 or the variable resistive element 21C shown in FIG. 17 may be provided in the above operational amplifier circuit 122A according to the first embodiment, the above operational amplifier circuit 122C according to the third embodiment, or the operational amplifier circuit 122D according to the fourth embodiment.

In addition, although the above embodiments 1 to 4 describe the examples, in each of which the present invention is applied to one example of commonly-used operational amplifier circuits, such a commonly-used operational amplifier circuit may be replaced by another well-known circuit configuration. For example, the above current source transistor 102 may be replaced by a cascade current mirror-type differential current source. In other words, each of the operational amplifier circuits 122A to 122F according to the first to fourth embodiments may further include a resistive element, which is connected between the current source transistor 102 and the node N1, for reducing variation of the current source transistor 102. This resistive element may be, for example, a transistor which has a gate voltage fixed at a bias voltage.

All processing units included in the display apparatus 10 shown in FIGS. 1 and 2 are implemented typically as integrated circuits; specifically, LSI. These units may be each formed into a single chip, and it is also possible to integrate part or all of these units in a single chip.

This circuit integration is not limited to the LSI and may be achieved by providing a dedicated circuit or using a general-purpose processor. It is also possible to utilize a field programmable gate array (FPGA), with which LSI is programmable after manufacture, or a reconfigurable processor, with which connections, settings, etc., of circuit cells in LSI are reconfigurable.

Furthermore, if any other circuit integration technology to replace LSI emerges thanks to semiconductor technology development or other derivative technology, such technology may, of course, be used to integrate these processing units.

Moreover, the processor for CPU or the like may execute a program to perform part of the functionality of the display apparatus 10.

Further, the present invention may be the above program or a recording medium on which the above program has been recorded. It goes without saying that the above program may be distributed via a communication network such as the Internet.

The present invention may be provided as an operational amplifier circuit adjusting method for reducing the output voltage variation occurring in one of the above operational amplifier circuits 122A to 122D. Further, the present invention may also be provided as an adjusting method for the display driving apparatus 10 or the display apparatus 10.

Moreover, the present invention may be implemented as an operational amplifier circuit adjusting system, which includes the above adjusting device and one of the operational amplifier circuits 122A to 122D, or may also be implemented as the display driving apparatus 110 or the display apparatus 100, which includes the above adjusting device. The functionality of this adjusting device may be performed by a dedicated circuit (hardware), or may be performed by program execution by a processor for CPU or the like (software), or may also be performed by combination of these hardware and software.

In addition, although the above explanation describes the examples where the operational amplifier circuits 122A to 122D according to the first to fourth embodiment of the present invention are each provided in the display apparatus 10 which includes the organic electroluminescent panel 111, the present invention may be applied to other display apparatuses. For example, the present invention may be applied to a display apparatus which includes a liquid crystal panel.

All the numbers herein are given as examples to provide specific explanations of the present invention, and the present invention is thus not restricted by those numbers. Further, the logic levels represented as HIGH/LOW or the switching states represented as ON/OFF are also given as examples to provide specific explanations of the present invention. It is therefore possible to obtain an equivalent result by different combinations of the above logic levels and switching states. The n-type and p-type of the transistor, for example, are given as examples to provide specific explanations of the present invention. It is therefore possible to obtain an equivalent result by providing transistors of opposite type. The connections among the elements are given as examples to provide specific explanations of the present invention, and other connections may be used, without limitation, to provide the functionality of the present invention.

It is possible to combine at least part of the functionalities of the operational amplifier circuits 122A to 122D according to the above first to fourth embodiments and Variations thereof.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to an operational amplifier circuit and a display apparatus. The present invention, which is capable of reducing output voltage variation of an operational amplifier circuit, is applied preferably to a power supply circuit and a flat panel driver. Moreover, the present invention is applicable to a portable device, a to compact mobile device, and a large panel device, each of which includes a liquid crystal panel or an organic electroluminescent panel.

What is claimed is:

1. An operational amplifier circuit comprising:
a differential amplifier unit including a first differential transistor and a second differential transistor, which form a first differential pair, and a current source transistor which supplies a current to the first differential pair; and
a first variable resistive element connected between (i) at least one of a source of said first differential transistor and a source of said second differential transistor and (ii) a drain of said current source transistor,
wherein said first variable resistive element includes:
a first terminal and a second terminal;
first resistive elements connected in series; and
a first correction voltage selecting circuit which modifies a resistance value between said first terminal and said second terminal by changing the number of stages of said first resistive elements connected in series between said first terminal and said second terminal.

2. The operational amplifier circuit according to claim 1, further comprising
a second variable resistive element,
wherein said first variable resistive element is connected between the source of said first differential transistor and the drain of said current source transistor, and
said second variable resistive element is connected between the source of said second differential transistor and the drain of said current source transistor, and includes:
a third terminal and a fourth terminal;
second resistive elements connected in series; and
a second correction voltage selecting circuit which modifies a resistance value between said third terminal and said fourth terminal by changing the number of stages of said second resistive elements connected in series between said third terminal and said fourth terminal.

3. The operational amplifier circuit according to claim 1, further comprising
a correction polarity switching circuit which switches between a first mode and a second mode,
wherein the first mode indicates that said first variable resistive element is not connected between the source of said second differential transistor and the drain of said current source transistor, but connected between the source of said first differential transistor and the drain of said current source transistor, and
the second mode indicates that said first variable resistive element is not connected between the source of said first differential transistor and the drain of said current source transistor, but connected between the source of said second differential transistor and the drain of said current source transistor.

4. The operational amplifier circuit according to claim 1, further comprising
a variable current source which selectively supplies a current having one of current values to the at least one of the source of said first differential transistor and the source of said second differential transistor.

5. The operational amplifier circuit according to claim 1, further comprising
a variable voltage circuit which selectively outputs a voltage having one of voltage values to a gate of said current source transistor.

6. The operational amplifier circuit according to claim 1,
Wherein said first correction voltage selecting circuit includes first switches, each of which is provided for a corresponding one of said first resistive elements and which creates electrical conduction and an electrical disconnect between both terminals of the corresponding one of said first resistive elements.

7. The operational amplifier circuit according to claim 6,
wherein said first resistive elements have different resistance values from one another.

8. The operational amplifier circuit according to claim 1,
Wherein said first correction voltage selecting circuit includes first switches, each of which has a terminal connected to one of both ends and a connection node of a series connection of said first resistive elements and the other terminal connected to either said first terminal or said second terminal.

9. The operational amplifier circuit according to claim 6,
wherein each of said first resistive elements has a temperature dependent resistance value of which dependence is opposite to dependence of temperature dependent resistance values of said first switches.

10. The operational amplifier circuit according to claim 1,
wherein said first differential transistor and said second differential transistor are n-channel MOS transistors.

11. The operational amplifier circuit according to claim 1,
wherein said first differential transistor and said second differential transistor are p-channel MOS transistors.

12. The operational amplifier circuit according to claim 1,
wherein said first differential transistor and said second differential transistor are n-channel MOS transistors, and
said differential amplifier unit further includes a third differential transistor and a fourth differential transistor, which are p-channel MOS transistors and form a second differential pair.

13. An operational amplifier circuit comprising:
a differential amplifier unit including a first differential transistor and a second differential transistor, which form a first differential pair, and a current source transistor which supplies a current to said first differential pair; and
a first variable resistive element connected between (i) at least one of a source of said first differential transistor and a source of said second differential transistor and (ii) a drain of said current source transistor,
wherein said first variable resistive element includes:
a first terminal and a second terminal;
a transistor having one of a source terminal and a drain terminal connected to said first terminal and the other one of the source terminal and the drain terminal connected to said second terminal; and
a variable voltage circuit which modifies on-resistance of said transistor by supplying a voltage having one of voltage values to said transistor.

14. The operational amplifier circuit according to claim 13,
wherein a constant voltage is applied to a gate terminal of said transistor, and
said variable voltage circuit modifies the on-resistance of said transistor by changing a substrate voltage of said transistor.

15. The operational amplifier circuit according to claim 13,
wherein a constant substrate voltage is applied to said transistor, and
said variable voltage circuit modifies the on-resistance of said transistor by changing a gate voltage of said transistor.

16. A display apparatus for displaying an image according to image data, comprising:
a display panel which displays the image; and
a display driving apparatus which drives said display panel,
wherein said display panel includes:
light emitting pixels arranged in rows and columns; and
source lines each being provided for a corresponding one of the rows or the columns, and
said display driving apparatus includes said operational amplifier circuits according to claim 1, each of which is provided for a corresponding one of said source lines and outputs a signal voltage according to the image data to the corresponding one of said source lines.

17. The display apparatus according to claim 16,
wherein said display panel is an organic electroluminescent panel.
